(19) United States
(12) Patent Application Publication
(10) Pub. No.: US 2017/0179198 A1
(43) Pub. Date: Jun. 22, 2017

(54) TANDEM ORGANIC PHOTOVOLTAIC DEVICES THAT INCLUDE A METALLIC NANOSTRUCTURE RECOMBINATION LAYER

(71) Applicant: CHAMP GREAT INT'L CORPORATION, Eden Island (SC)

(72) Inventors: Ning Li, Erlangen (DE); Johannes Krantz, Erlangen (DE); Tobias Stubhan, Nürnberg (DE); Florian Machui, Erlangen (DE); Tayebeth Ameri, Nürnberg (DE); Christoph Brabec, Linz (AT)

(21) Appl. No.: 15/115,903

(22) PCT Filed: Jan. 31, 2014
(86) PCT No.: PCT/US14/14263

§ 371 Date: Aug. 1, 2016

(51) Int. Cl. H01L 27/30; H01L 51/44; H01L 51/42; H01L 51/00

(52) U.S. Cl. CPC H01L 27/302; H01L 51/0021; H01L 51/442; H01L 51/4253; H01L 51/0037; H01L 51/0035; H01L 51/0047; H01L 51/0036

(57) ABSTRACT

An intermediate layer (110) useful for coupling two individual organic photovoltaic devices (600) to provide a tandem organic photovoltaic device includes a first hole transport layer (114), a first electron transport layer (112), and a metallic nanostructure layer (116) interposed between the first hole transport layer (114) and the first electron transport layer (112). The metallic nanostructure layer (116) provides an efficient recombination point for electrons and holes. The metallic nanostructure layer (116) can include silver nanowires which providing outstanding optical properties and permit the formation of the metallic nanostructure layer (116) using a low temperature, solution based, process that does not adversely affect underlying layers.

### BACKGROUND

Technical Field

This invention is related to organic photovoltaic devices, and in particular to intermediate layers for use with tandem organic photovoltaic devices.

Description of the Related Art

With an increasing emphasis on carbon neutral energy production, and given the abundant supply of solar energy received by the earth, photovoltaics are gaining traction as an attractive energy source. Currently, wafer-based crystalline silicon technologies and processes produce the vast majority of photovoltaic devices, such as solar cells. Recent developments in organic photovoltaics, particularly in the development of film based organic photovoltaic devices using organic semiconductors have demonstrated improved efficiencies, at times achieving efficiencies greater than 10%. Organic photovoltaic devices such as organic solar cells are attractive because of their relative ease of processing, inherent physical flexibility, and potential low cost of fabrication for large solar collection devices, particularly when compared to more conventional silicon wafer based photovoltaics.

In contrast to conventional semiconductor based photovoltaic devices in which charge separation occurs due to the electric fields inherent in the semiconductor, in organic photovoltaics, charge separation occurs in an active layer comprising an electron donor material (i.e., a hole transport layer or “HTL”) combined with an electron acceptor material (i.e., an electron transport layer or “ETL”). Within the active layer of an organic photovoltaic, incident photons having an energy level at least equal to the energy difference between the highest occupied molecular orbital and the lowest unoccupied molecular orbital may result in the formation of an exciton, a bound electron/hole pair. To a large extent, the efficiency of an organic photovoltaic is dependent upon separating or dissociating the electron and hole pair forming the exciton. Once dissociated, in a single layer organic photovoltaic cell (i.e., an organic photovoltaic comprising only an anode, active layer, and cathode), the active layer transports a portion of the dissociated holes and electrons to the cell cathode and anode, respectively, to provide an electrical output.

The power conversion efficiency (“PCE”) of an organic photovoltaic device depends, at least in part, upon the absorption spectra of the electron donor used in the active layer. Electron donors having narrow absorption spectra generally result in a decreased short circuit current density (J_{SC}). The PCE of an organic photovoltaic device is also dependent upon thermalization losses attributable to the energy carried by photons exceeding the energy difference between the highest occupied molecular orbital and the lowest unoccupied molecular orbital. Such thermalization losses occur when excess photonic energy converts to thermal energy (i.e., heat) within the active layer. Such thermal energy or heating within the active layer tends to decrease the open circuit voltage (V_{OC}) produced by the organic photovoltaic device.

Accordingly, there remains a need in the art to improve the power conversion efficiency of organic photovoltaic devices by broadening absorption spectra of the active layers used in such organic photovoltaic devices while reducing thermalization losses in such organic photovoltaic device.

### BRIEF SUMMARY

Tandem organic photovoltaic devices stack two or more organic photovoltaic devices having complementary absorption spectra in an electrical series or parallel connection. Such construction broadens the absorption spectra of the tandem device thereby increasing the short circuit current density (JSC) while decreasing the thermalization effects thereby increasing the open circuit voltage (VOC) produced by the tandem organic photovoltaic device. A primary challenge in constructing a practical tandem organic photovoltaic device is the intermediate layer used to couple the two individual organic photovoltaic devices forming the tandem organic photovoltaic device. The intermediate layer generally lies between the active layer of the first organic photovoltaic device and the active layer of the second organic photovoltaic device. Generally, the intermediate layer is most desirably highly transparent, conductive, and sufficiently robust to protect the underlying layers of the organic photovoltaic device. Since many of the underlying layers forming the organic photovoltaic device are thermally sensitive, the processing steps required to create the intermediate layer are preferably performed at low temperatures, for example through solution processing or similar rather than a thermal deposition process.

Example optical stacks that include one or more transparent or semi-transparent layers are described herein. An exemplary optical stack may include a first hole transport layer forming at least a portion of the first surface, a first electron transport layer forming at least a portion of the second surface. A metallic nanostructure layer including a plurality of metallic nanostructures interposed between the first hole transport layer and the first electron transport layer. The plurality of metallic nanostructures can include silver nanowires, silver nanodots, or any combination thereof. A longitudinal axis of each of the plurality of silver nanowires may be arranged parallel or substantially parallel to the first surface, the second surface, or both the first surface and the second surface. A longitudinal axis of each of the plurality of silver nanodots may be arranged at a non-zero angle with respect to the first surface, at a non-zero angle with respect to the second surface, or a non-zero angle with respect to both the first surface and the second surface.

Example tandem organic photovoltaic devices are described herein. An exemplary organic photovoltaic device includes an intermediate layer that incorporates a metallic nanostructure layer disposed between a first organic photovoltaic device and a second organic photovoltaic device. The intermediate layer includes a first hole transport layer disposed proximate the first organic photovoltaic device, a first electron transport layer disposed proximate the second organic photovoltaic device and the metallic nanostructure layer disposed between the first hole transport layer and the first electron transport layer. In at least some implementations, the metallic nanostructure layer may include silver nanowires, silver nanodots, or combinations thereof. Surprisingly, metallic nanostructures in the form of metallic nanodots provided efficient recombination sites for series connected tandem organic photovoltaic devices while metallic nanostructures in the form of metallic nanowires provided an efficient electrode for tandem organic photovoltaic devices connected in parallel.

Example methods of manufacturing tandem organic photovoltaic devices are also described herein. An exemplary method includes a first organic photovoltaic device having a surface, forming a first hole transport layer across all or a portion of the surface of the first organic photovoltaic device. The method further includes depositing a solution including a plurality of metallic nanostructures at a first concentration across all or a portion of the first hole transport layer. The method additionally includes leveling the deposited metallic nanostructure solution across substantially all of the first hole transport layer. The method also includes forming a first electron transport layer across all or a portion of the leveled metallic nanostructure layer. The method further includes forming a second organic photovoltaic device across all or a portion of the first electron transport layer after forming a first electron transport layer.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and have been selected solely for ease of recognition in the drawings.

FIG. 1 depicts a single junction organic photovoltaic device having a recombination layer that includes a hole transport layer, a metallic nanostructure layer, and an electron transport layer, according to an embodiment described herein.

FIGS. 2A-2C depict a single junction organic photovoltaic device and the transmission properties of various hole transport layer, metallic nanostructure layer, and electron transport layer combinations, according to an embodiment described herein.

FIGS. 3A-3I are two and three dimensional atomic force microscopy (AFM) images and height profiles associated with various intermediate layer material combinations, according to an embodiment described herein.

FIGS. 4A-4D depict short circuit current density versus open circuit voltage graphs for organic photovoltaic devices using various intermediate layer material combinations, according to an embodiment described herein.

FIG. 5 depicts a chart providing short circuit current density and open circuit voltage characteristics for organic photovoltaic devices using various intermediate layer material combinations, according to an embodiment described herein.

FIG. 6 depicts a tandem organic photovoltaic device having an intermediate recombination layer that includes a hole transport layer, a metallic nanostructure layer, and an electron transport layer, according to an embodiment described herein.

FIGS. 7A-7F depict a tandem organic photovoltaic device and the short circuit current density versus open circuit voltage graphs for such organic photovoltaic devices using various intermediate layer material combinations, according to an embodiment described herein.

FIG. 8 depicts a chart providing short circuit current density and open circuit voltage characteristics for a tandem organic photovoltaic device using various intermediate layer material combinations, according to an embodiment described herein.

FIG. 9 depicts an illustrative method of forming a tandem organic photovoltaic device having an intermediate layer that includes a metallic nanostructure layer interposed between a first organic photovoltaic device and a second organic photovoltaic device, according to an embodiment described herein.

FIG. 10 depicts an illustrative method of forming a tandem organic photovoltaic device by depositing an intermediate layer that includes a metallic nanostructure layer interposed between a first organic photovoltaic device and a second organic photovoltaic device, according to an embodiment described herein.

### DETAILED DESCRIPTION

Organic photovoltaic devices and methods for forming the same are described herein in various embodiments. It should be understood that variations are possible within each of these embodiments and in other embodiments not specifically described for the sake of clarity and/or to avoid redundancy within this disclosure. Additionally, the order, extent, and composition of the various layers and structures disclosed herein can be varied, altered, divided, or subdivided to meet varying performance specifications.

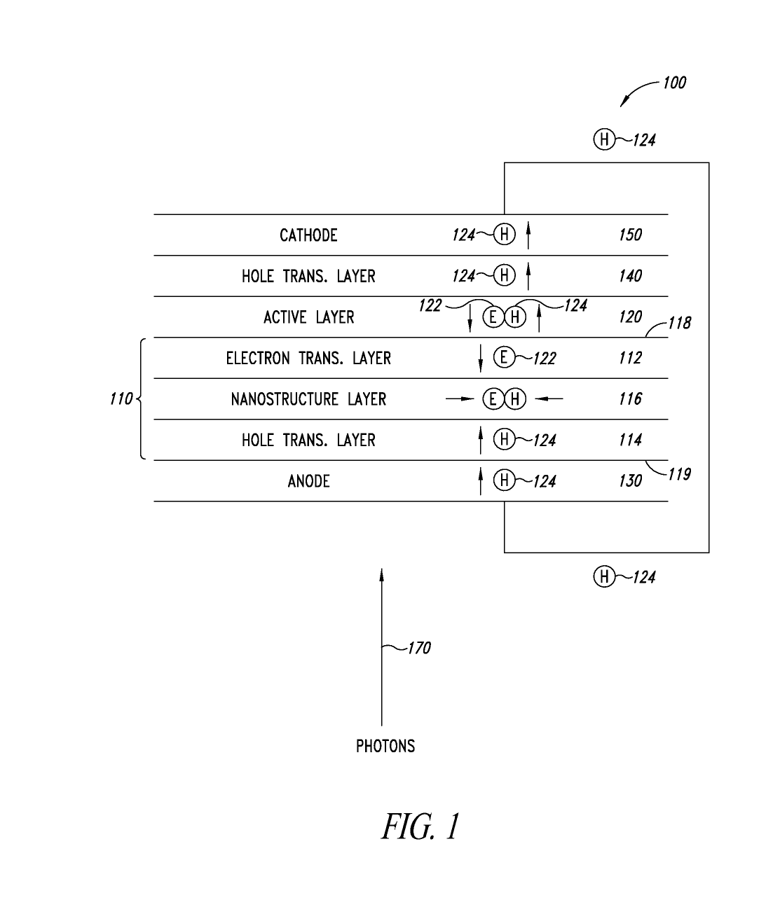

FIG. 1 illustrates an organic photovoltaic device comprising an intermediate layer 110 that includes an electron transport layer 112, a hole transport layer 114, and a metallic nanostructure layer 116 interposed between the active layer 120 and a first electrode 130 of a single junction organic photovoltaic 100. The single junction organic photovoltaic 100 further includes a hole transport layer 140 deposited between the active layer 120 and a second electrode 150.

Electromagnetic radiation in the form of photons 170 enters the single junction organic photovoltaic device 100 in the indicated direction. The first electrode 130 includes a transparent or translucent conductor such as indium tin oxide (ITO) deposited on a glass substrate. The photons 170 penetrate the intermediate layer 110 and enter the active layer 120. The active layer 120 includes one or more electroactive compounds sensitive to photons falling within a defined band of wavelengths. The electroactive compounds within the active layer 120 include one or more electron donors and one or more hole donors (i.e., electron acceptors). In some implementations such electron donors and hole donors are deposited in discrete layers to form the active layer 120 while in other implementations the electron donors and hole donors are mixed to form a blended active layer 120. An example of an electron donor useful in the active layer 120 includes fullerene containing or fullerene based compounds such as phenyl-C61-butyric acid methyl ester (“PCBM”). An example of a hole donor useful in the active layer 120 includes poly(3-hexylthiophene-2,5-diyl) (“P3HT”). Although PCBM and P3HT are provided as illustrative examples of an electron donor and a hole donor, respectively, those of skill in the art will appreciate that other current and future developed electron donors and hole donors may be used as well.

The interaction of photons incident upon the organic photovoltaic device with the electroactive organic electron donors and electroactive organic electron acceptors forming the active layer, cause the formation of bound electron/hole pairs (“excitons”) in the active layer. Excitons form when photons having an energy level at or above the activation energy required to excite an electron from the highest occupied molecular orbital (“HOMO”) to the lowest unoccupied molecular orbital (“LUMO”) interact with the electron donors and acceptors in the active layer. Once formed, the exciton either relaxes to the ground state (i.e., the electron returns to the former HOMO) or dissociates into an electron and a hole. The dissociation and migration of the electron and hole to the respective electrodes of an organic photovoltaic device creates a DC voltage between the electrodes.

In a traditional organic photovoltaic device, a hole transport layer may be disposed between the active layer 120 and the second electrode 150 to promote the dissociation of excitons at the active layer/hole transport layer interface and to facilitate the movement of holes to the second electrode 150. Similarly, an electron transport layer may be disposed between the active layer 120 and the first electrode 130 to promote the dissociation of excitons at the active layer/electron transport layer interface and to facilitate the movement of electrons to the first electrode 130.

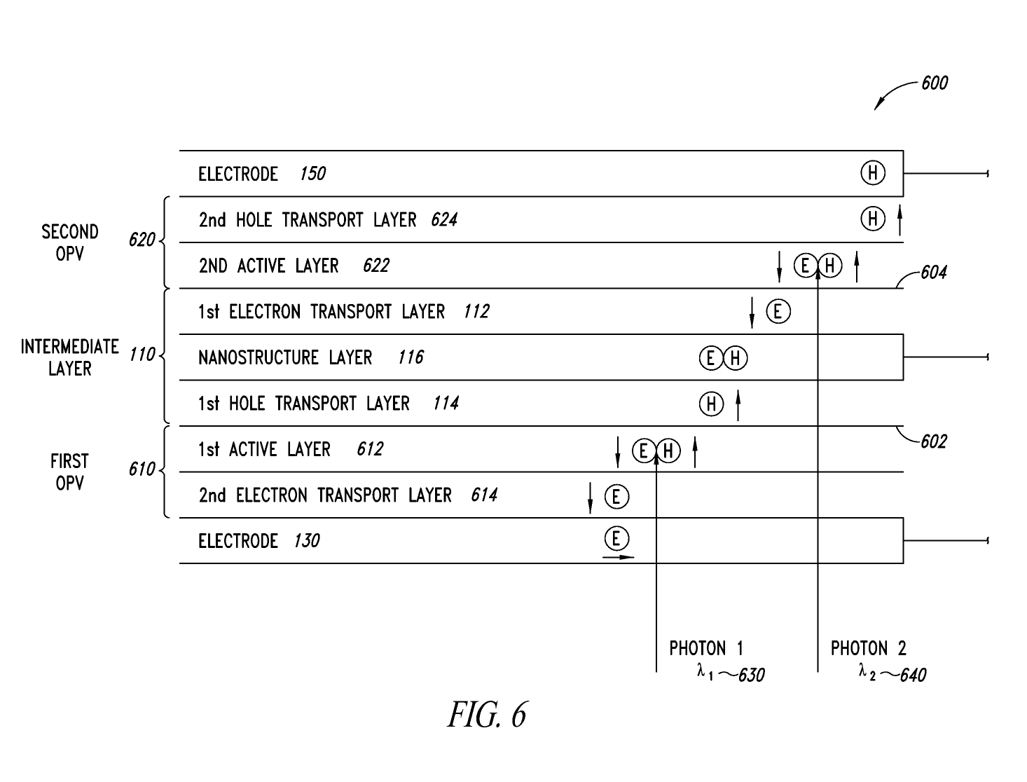

In a tandem organic photovoltaic device (discussed in detail beginning with FIG. 6), two or more organic photovoltaic devices (“subcells”) are physically and electrically coupled to an intervening intermediate layer 110 to form a “stack.” The efficiency of tandem organic photovoltaic devices is dependent, at least in part, on minimizing or ideally avoiding the formation of a charge accumulation within the intermediate layer interposed between the organic photovoltaic devices in the stack. Several mechanisms contribute to charge accumulation within the intermediate layer; however, at least a portion of such charge accumulation is may be attributable to the inability of the intermediate layer to promote or otherwise facilitate the recombination of holes and electrons transported to the intermediate layer from the adjacent active layers.

In the single junction organic photovoltaic device 100, holes 124 separated from excitons produced in the active layer 110 are introduced via the first electrode 130 to the hole transport layer 114. The electron transport layer 112 receives at least some of the electrons 122 separated from excitons produced in the active layer 110. As configured in FIG. 1, the metallic nanowire layer 116 should efficiently promote the recombination of electrons 122 and holes 124 while minimizing charge accumulation within the intermediate layer 110.

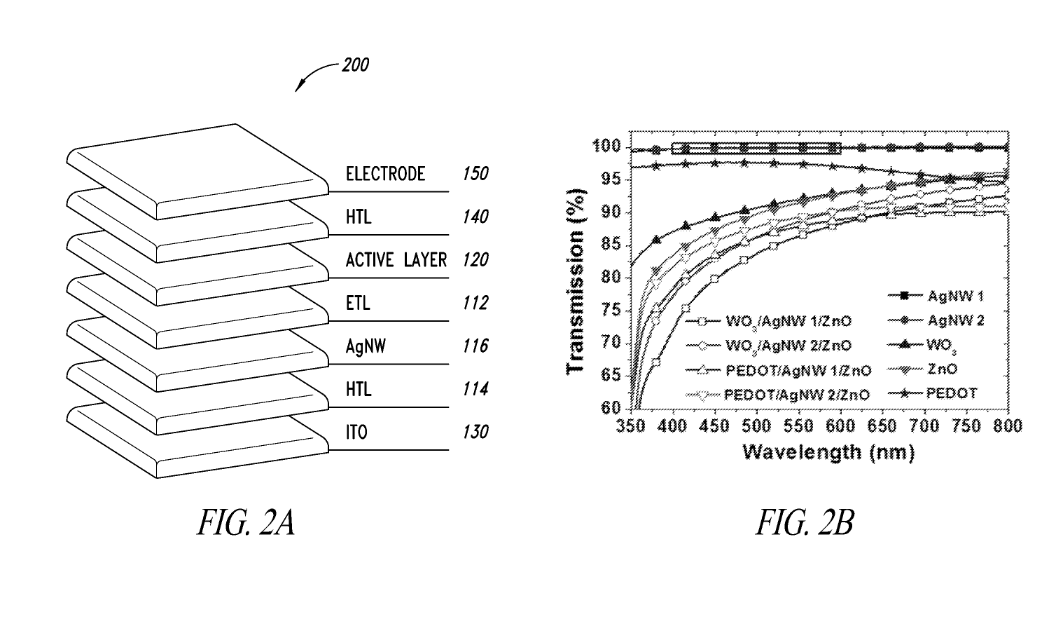

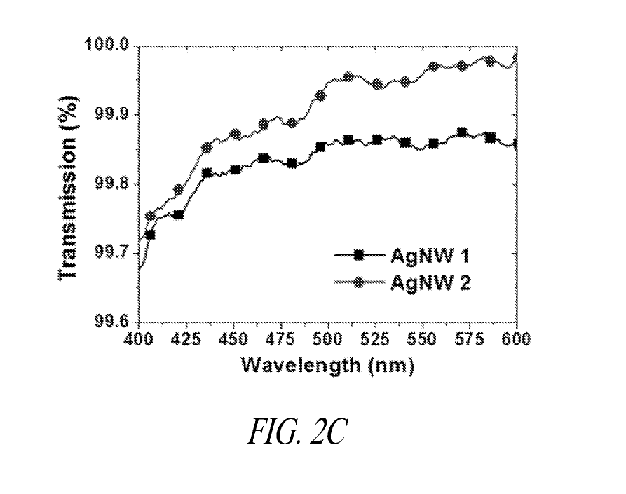

FIG. 2A depicts an exemplary single junction organic photovoltaic device 200 useful for evaluating the recombination efficiency of various intermediate layers 110 using different electron transport layer 112 materials and different hole transport layer 114 materials in combination with a metallic nanostructure layer 116. In at least some implementations, the metallic nanostructure layer 116 may include silver nanostructures, for example silver nanowires and/or silver nanodots.

A liquid suspension, slurry, or solution containing metallic nanostructures may be applied to the hole transport layer 114 at relatively low temperatures and in the absence of oxygen. In at least some implementations, such liquids may be in the form of an ink containing one or more solvents, surfactants, and viscosity modifier or binder to maintain the metallic nanostructures in a stable dispersion. Such inks are amenable to spin coating or mechanical scraping application at relatively low temperatures, which is advantageous when such inks provide the metallic nanostructure layer 116 over a thermally sensitive substrate or organic photovoltaic layer.

FIGS. 2B and 2C show the transmission spectra of various compounds and compound combinations useful for providing an intermediate layer 110 used in the single junction organic photovoltaic device 200 depicted in FIG. 2A. For test purposes, all of the intermediate layers were deposited on a glass substrate via doctor blading. In evaluating the transmission spectra, poly(3,4-ethylenedioxythiophene)/poly(styrenesulfonate) (“PEDOT:PSS”) was coated to a thickness of 50 nanometers (nm); tungsten oxide (“WO₃”) to a thickness of 60 nm and zinc oxide (“ZnO”) to a thickness of 120 nm. PEDOT:PSS AI4083 was purchased from Heraeus and diluted in isopropyl alcohol (“IPA”) at a volume-ratio of 1:3 or 1:5 before processing. ZnO nanoparticles were synthesized from zinc acetate and dissolved in ethanol at 2 weight percent (wt. %). WO₃ nanoparticles were synthesized from flame pyrolysis and dissolved at 2.5 wt. % in ethanol. Silver nanostructure (hereinafter “AgNW”) ink was prepared from a silver nanowire ink master solution containing between 0.1 wt. % and 5 wt. % silver nanowires that is diluted with isopropyl alcohol at a volume-ratio of 1:5 (hereinafter “AgNW1”) or 1:10 (hereinafter “AgNW2”). To provide the metallic nanostructure layer 116 used in the intermediate layer 110. To evaluate the transmission spectra of the intermediate later 110, a thin layer of the silver nanostructure ink (i.e., the metallic nanostructure layer 116) was bladed between the electron transport layer 112 and the hole transport layer 114.

Many metallic nanostructure layers, for example silver nanostructure layers, demonstrate outstanding transparency. After correction for the substrate, in the configuration depicted in FIG. 2A transmission values of over 99% for wavelengths between 400 to 600 nm were observed. The metal oxides WO₃ and ZnO demonstrate reduced transmittance in the blue portion of the spectrum, while PEDOT:PSS demonstrates reduced transmittance in the infrared portion of the spectrum. Transmittance of the charge extraction (i.e., electron and hole transport) layers 112, 114 is generally in excess of 90%. The intermediate layer 110 combinations predominantly absorb in the blue regime, and their transmittance does not appear to be a linear combination of the transmittance of the individual layers used in forming the intermediate layer 110. It is surmised that a thin film interference phenomena may control absorption in the thin film and the insertion of metallic nanoparticle layer 116 does not appear to have a significant effect on the overall transmittance of the intermediate layer 110. Of note, the various electron transport layer 112, metallic nanostructure layer 116, and hole transport layer 114 combinations demonstrated excellent optical properties with overall transmittance in excess of 85%.

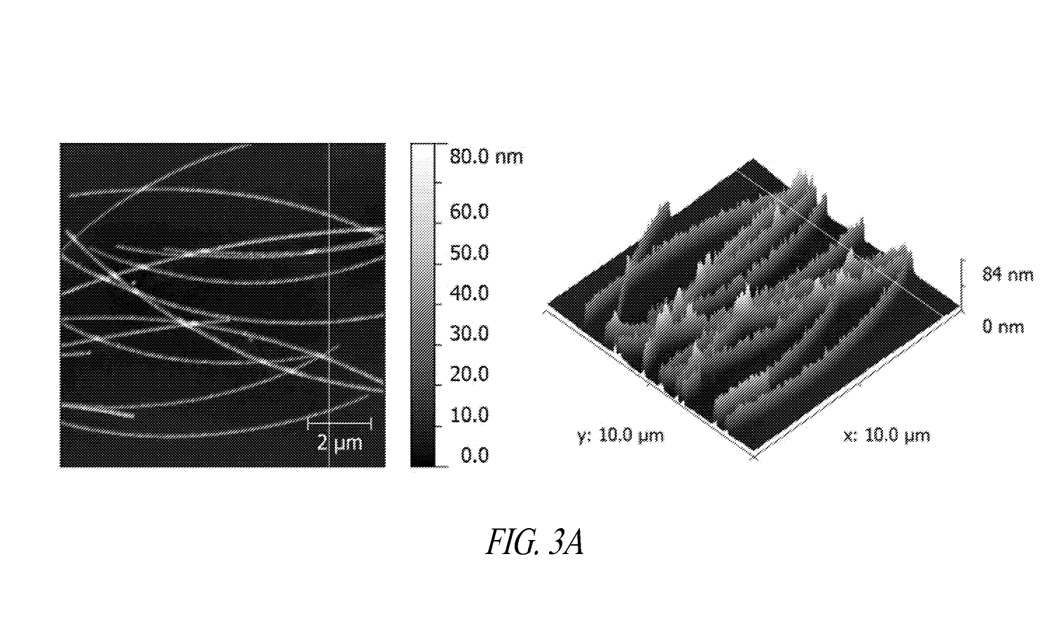

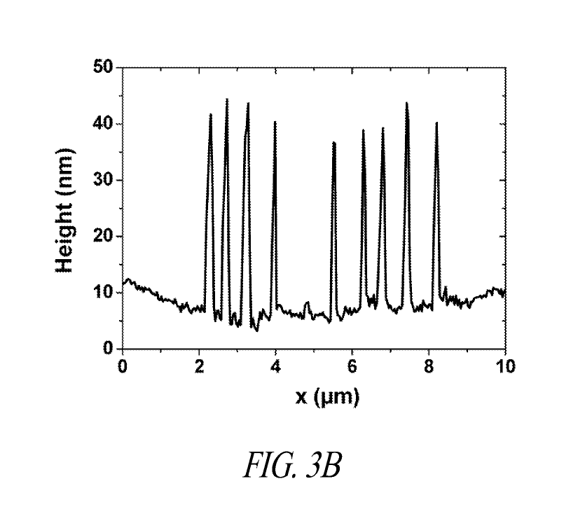

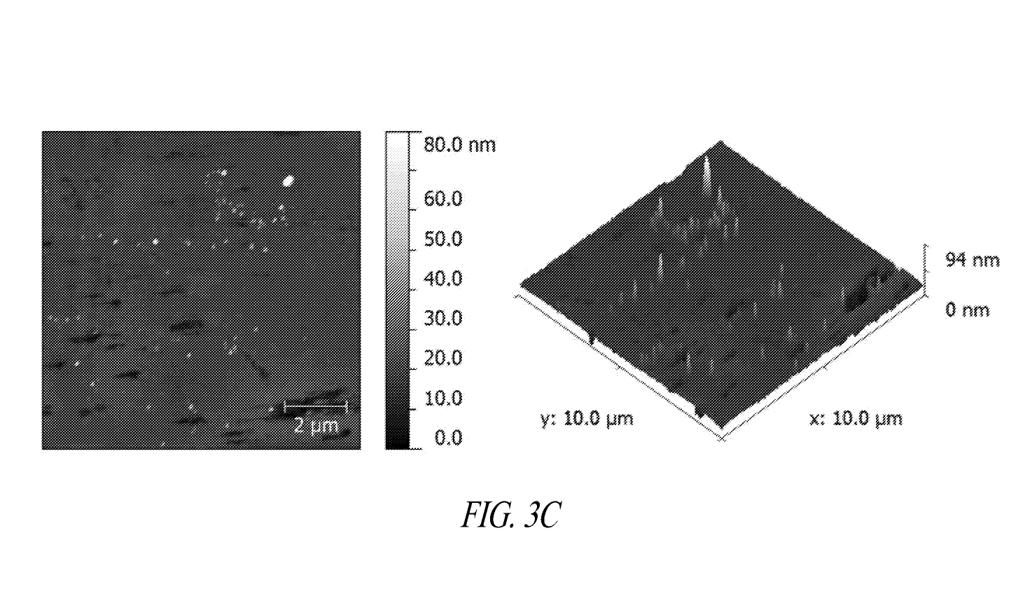

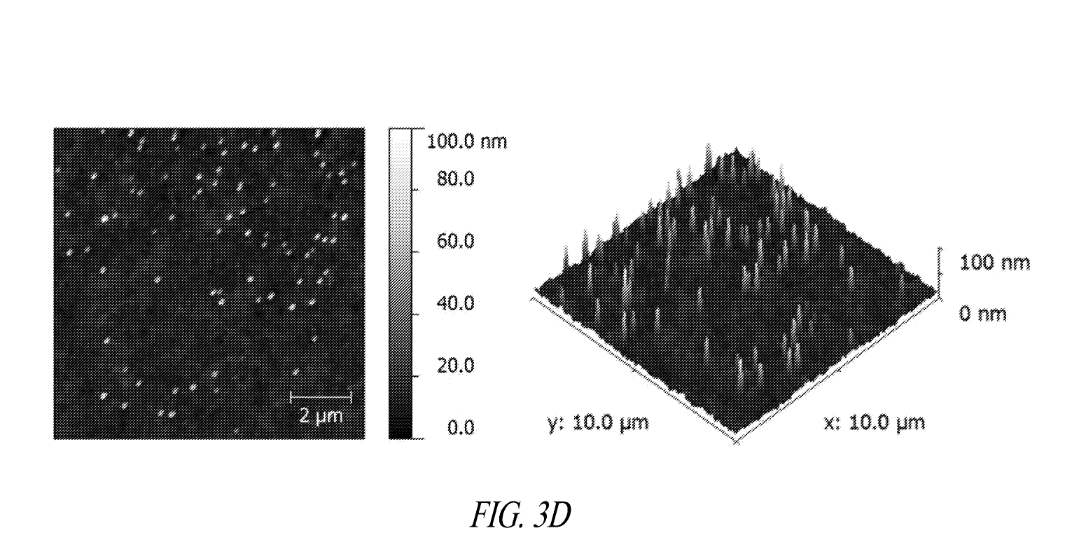

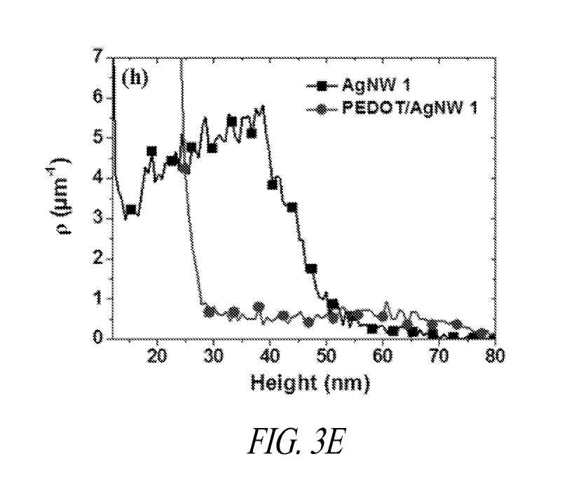

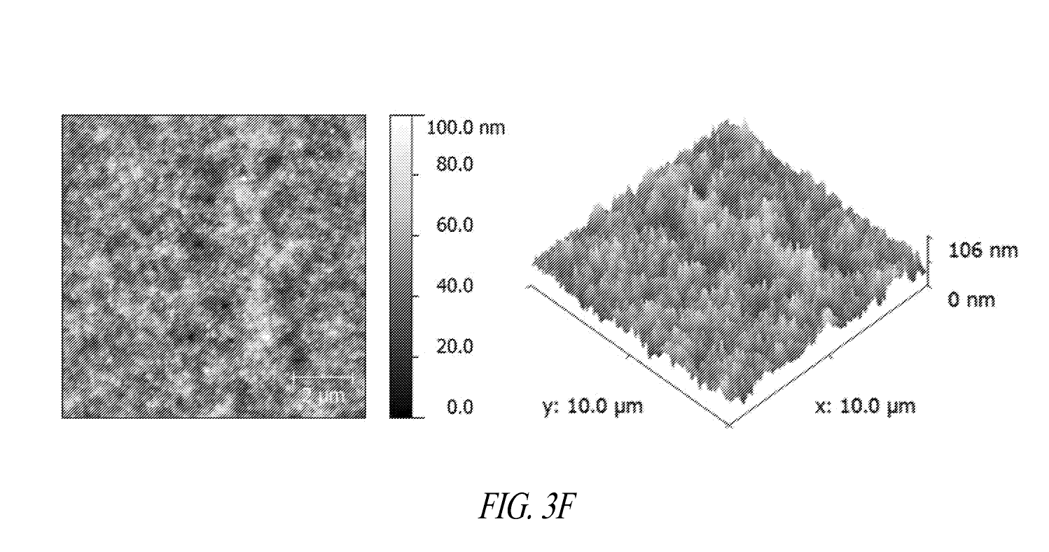

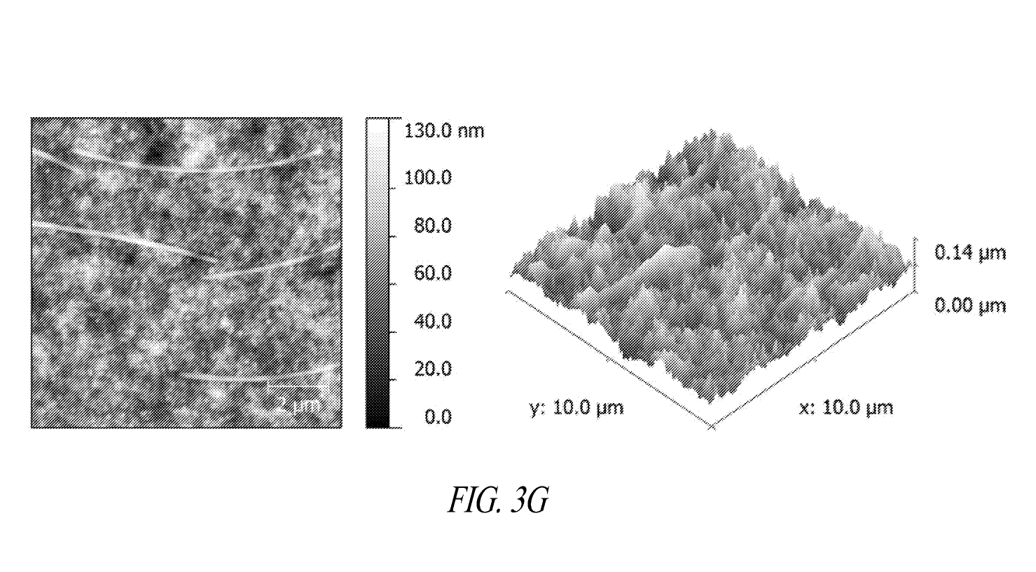

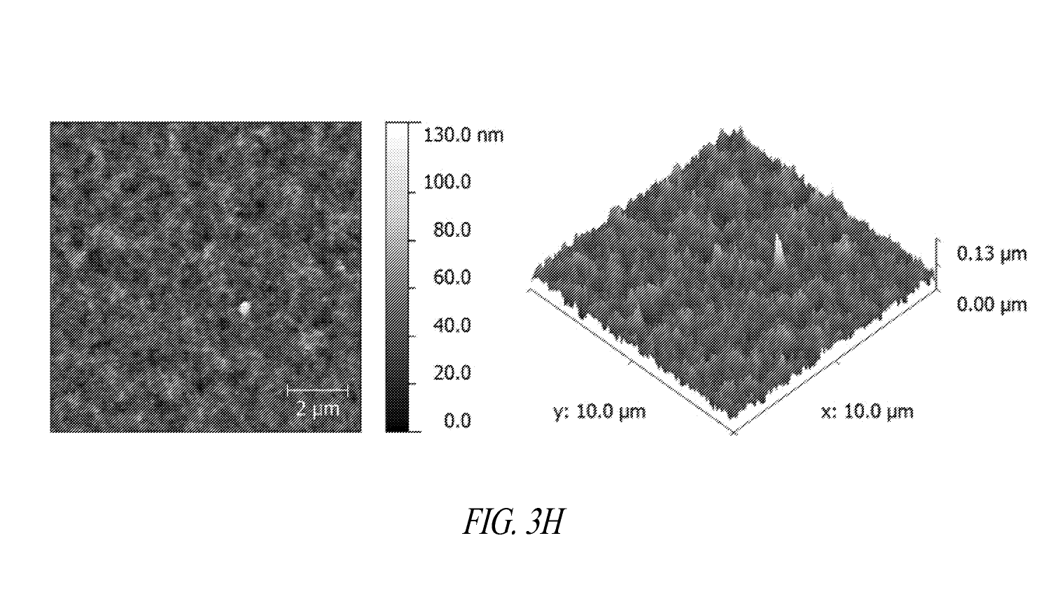

FIG. 3A provides two and three dimensional atomic force microscopy (“AFM”) images of a nanostructure layer formed by the deposition of the relatively concentrated (1:5 v/v dilution with IPA) AgNW1 ink on a glass substrate. From the AFM images, the metallic nanostructures in the metallic nanostructure layer 116 are composed predominantly of silver nanowires along with a few silver nanodots (i.e., the physically degraded and/or truncated silver nanowires, or silver nanoparticles that co-precipitated with the silver nanowires and were formulated into the AgNW ink). The silver nanodots may either be produced during the application process or be vestigial remnants of the silver nanowire synthesis process. A polyol process provides the silver nanowire synthesis process. The polyol process requires the presence of one or more polymeric binders such as poly(vinylpyrrolidone) (“PVP”). Polymeric binders provide a polymeric matrix for the silver nanowires to form the nanostructure layer 116 depicted in FIG. 2A In at least some instances, the silver nanodots such as those visible in FIG. 3A may be cladded and embedded in the polymer binder during the silver nanowire synthesis process.

FIG. 3B provides a height profile of the nanostructure layer 116 formed by the deposition of the relatively concentrated AgNW1 ink depicted in FIG. 3A. The height value shown in FIG. 3B indicates the thickness of the polymeric binder forming the matrix backbone is about 10 nanometers (nm) and the silver nanowires have a diameter of about 30 nm. Of note, the physical structure and appearance of the silver nanowires in the metallic nanostructure layer 116 appears relatively unchanged from the silver nanowires in the relatively concentrated silver nanowire ink (“AgNW1”) deposited to form the metallic nanostructure layer 116. Within FIGS. 3A and 3B, locations where two or more nanowires overlap show good correspondence with the expected thickness based on a nanowire diameter of about 30 nanometers (nm).

FIG. 3C provides two and three dimensional atomic force microscopy (“AFM”) images of a nanostructure layer formed by the deposition of the relatively dilute (1:10 v/v dilution with IPA) AgNW2 ink on a glass substrate. From the AFM images, the resultant metallic nanostructure layer 116 formed by the deposition of the relatively dilute AgNW2 ink on the glass substrate appears to surprisingly produce a metallic nanostructure layer composed primarily if not exclusively of metallic nanodots rather than metallic nanowires. It is surmised that the formation of silver nanodots results from an at least partial degradation of the silver nanowires present in the relatively dilute AgNW2 ink. Such nanowire degradation may be due at least in part to a physical degradation attributable to the mechanical leveling of the metallic nanostructure layer on the glass substrate.

FIG. 3D provides two and three-dimensional AFM images of a nanostructure layer formed by the deposition of the relatively concentrated AgNW1 ink on a PEDOT substrate. In contrast to the silver nanowires evident in FIG. 3A resulting from the deposition of the AgNW1 ink on a glass substrate, the AFM images in FIG. 3D indicate silver nanodots are formed when the relatively concentrated AgNW1 ink is applied over a PEDOT substrate.

FIG. 3E summarizes the height distributions of the relatively concentrated AgNW1 ink on the glass substrate depicted in FIG. 3A and the relatively concentrated AgNW1 ink on the PEDOT substrate depicted in FIG. 3C. The curves in FIG. 3E indicate the height distributions of silver nanowires (ref. FIG. 3A—AgNW1 on glass substrate) and silver nanodots (ref. FIG. 3D—AgNw1 ink on PEDOT substrate). In FIG. 3E, the silver nanowires demonstrate a height distribution ranging from about 10 nanometers (nm) to about 60 nanometers. In FIG. 3E, the silver nanodots demonstrate a height distribution ranging from about 30 nm to about 80 nm. FIG. 3E indicates the majority of the silver nanowires present in the metallic nanostructure layer on glass substrate depicted in FIG. 3A extend to a height of about 50 nanometers (nm) or less above the glass substrate. FIG. 3E also indicates the majority of the silver nanodots present in the metallic nanostructure layer on the PEDOT substrate depicted in FIG. 3C extend to a height of about 30 nm or less above the PEDOT substrate. Importantly, in both instances, a zinc oxide electron transport layer 112 having a depth of about 120 nm will completely cover the silver nanowires and/or silver nanodots present in the metallic nanostructure layer 116.

FIG. 3F provides two-dimensional and three-dimensional AFM images of a tungsten oxide (WO₃) layer formed on a glass substrate. FIG. 3G provides two-dimensional and three-dimensional AFM images of a metallic nanostructure layer formed by the deposition of the relatively concentrated AgNW1 ink on the tungsten oxide layer such as that depicted in FIG. 3F. FIG. 3H provides two-dimensional and three-dimensional AFM images of a metallic nanostructure layer formed by the deposition of the relatively dilute AgNW2 ink on a tungsten oxide layer such as that depicted in FIG. 3F. In comparing FIGS. 3G and 3H, it is apparent the metallic nanostructure layer (i.e., the silver nanowire layer) deposited on the tungsten oxide layer using the AgNW1 ink (ref. FIG. 3G) bears similar physical characteristics and appearance to the metallic nanostructure layer (i.e., the silver nanowire layer) deposited on the tungsten oxide substrate using the AgNW2 ink (ref. FIG. 3H). The average roughness (Rₘₛ) of the tungsten oxide layer deposited on the glass substrate (FIG. 3F) and the metallic nanostructure layer formed on the tungsten oxide layer using the relatively dilute AgNW2 ink (FIG. 3H) were measured to be 6.5 nanometers (nm) and 8 nm, respectively. The about 2 nm on average increase in observed roughness after mechanically leveling the relatively dilute AgNW2 ink over the tungsten oxide layer is similar to the increase in observed roughness after mechanically leveling the AgNW2 ink on the glass substrate.

FIG. 3I provides the height distributions of the relatively concentrated AgNW1 ink on the glass substrate depicted in FIG. 3D, the relatively concentrated AgNW1 ink on the tungsten oxide layer depicted in FIG. 3E, and the relatively dilute AgNW2 ink on the tungsten oxide layer depicted in FIG. 3F. After mechanically leveling the silver nanowire inks on the tungsten oxide layer, the mean value of the height distributions increased from about 56 nm (for tungsten oxide on glass—FIG. 3D) to about 80 nm (for silver nanowires using AgNW1 or AgNW2 inks on the tungsten oxide substrate). The 30 nm increase in mean value of the height distributions accords with the diameter of the silver nanowires used in preparing both the relatively concentrated AgNW1 and relatively dilute AgNW2 inks (ref. FIG. 3B).

Summarizing, the physical characteristics and composition of the mechanically leveled (e.g., doctor bladed) metallic nanostructure layer is affected by the composition of the substrate upon which the metallic nanostructure layer is deposited. A metallic nanostructure layer including silver nanowires formed on a tungsten oxide substrate does not show appreciable physical differences from the same metallic nanostructure layer applied to a glass substrate. Conversely, a metallic nanostructure layer including silver nanowires formed on a PEDOT substrate shows an appreciable physical difference from the same metallic nanostructure layer applied to a glass substrate, particularly when the metallic nanostructure layer is formed using a relatively concentrated ink such as AgNW1. When applied over a PEDOT substrate, a silver nanowire ink forms a metallic nanostructure layer that includes both nanowires and nanodots. Additionally, the concentration of the silver nanowire ink affects the eventual form of the silver nanostructures present in the metallic nanostructure layer.

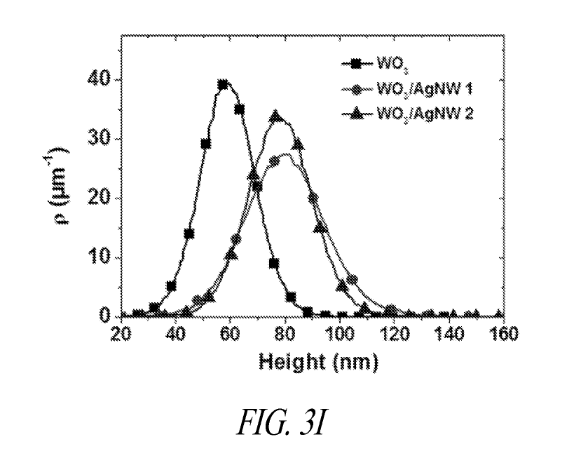

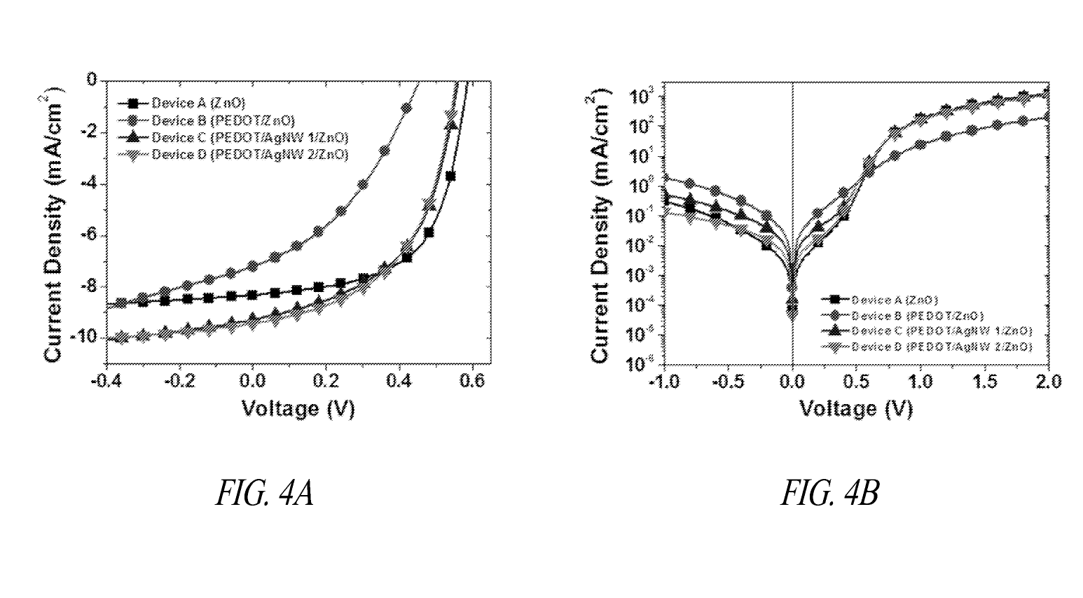

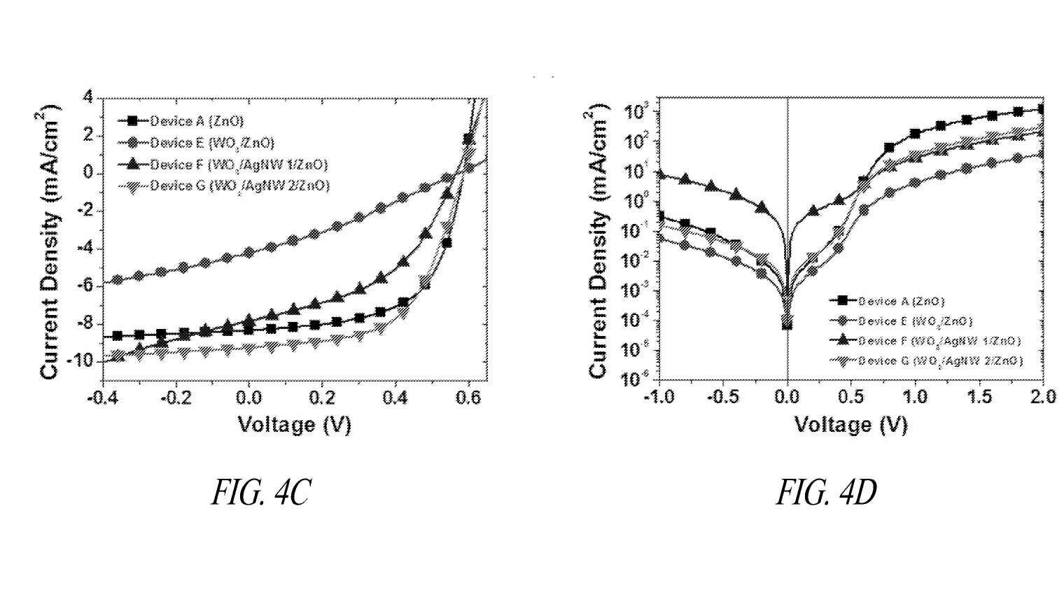

FIGS. 4A and 4B show a number of short circuit current density (“J”) versus open circuit voltage (“V”) graphs for single junction organic photovoltaic devices using different intermediate layer compositions. FIGS. 4A and 4B show J-V characteristics for four different single junction organic photovoltaic devices. A first curve (“Device A”—solid squares) shows the J-V characteristic for a reference single junction organic photovoltaic device 100 in which the intermediate layer 110 consists of a zinc oxide electron transport layer 112. A second curve (“Device B”—solid circles) shows the J-V characteristic for a single junction organic photovoltaic device 100 in which the intermediate layer 110 consists of a zinc oxide electron transport layer 112 and a PEDOT hole transport layer 114. A third curve (“Device C”—solid triangles) shows the J-V characteristic for a single junction organic photovoltaic device 100 in which the intermediate layer 110 consists of a zinc oxide electron transport layer 112, a PEDOT hole transport layer 114, and an intervening metallic nanostructure layer 116 deposited using the relatively concentrated AgNW1 ink. A fourth curve (“Device D”—inverted triangles) shows the J-V characteristic for a single junction organic photovoltaic device in which the intermediate layer 110 consists of a zinc oxide electron transport layer 112, a PEDOT hole transport layer 114, and an intervening metallic nanostructure layer 116 deposited using the relatively dilute AgNW2 ink.

As depicted in FIGS. 4A and 4B, significant limitations exist for the PEDOT/zinc oxide intermediate layer 110. The most obvious limitation is the rather low injection under forward bias, resulting in a low fill factor (“FF”). The PEDOT/zinc oxide intermediate layer 110 appears to provide an ineffective recombination and consequently is of marginal value for use as an intermediate layer 110 providing recombination capability in a tandem organic photovoltaic device. Notably, solution processed zinc oxide is not well defined in terms of its semiconducting and electrical properties (e.g., density of states and density of charge carriers) and such properties may differ for various production processes and routes. Moreover, the chemical nature and the density of the ligand groups terminating the zinc oxide surface which are essential for contact/interface formation, are very difficult to assess and not well known for most systems. However, interposing or otherwise depositing a metallic nanostructure layer 116 between the zinc oxide electron transport layer 112 and the PEDOT hole transport layer 114 in the intermediate layer 110 appears to mitigate or even overcome the identified issues with the use of a zinc oxide electron transport layer 112. Interposing a metallic nanostructure layer 116, for example a silver nanostructure layer 116 formed from an AgNW1 ink or an AgNW2 ink, between the zinc oxide electron transport layer 112 and the PEDOT hole transport layer 114 significantly improves the charge recombination within the intermediate layer 110. Consequently, the organic photovoltaic devices using intermediate layers 110 that include a metallic nanostructure layer 116 exhibit performance comparable to the reference organic photovoltaic device (Device A) using a single zinc oxide electron transport layer.

FIGS. 4C and 4D show a number of short circuit current density (“J”) versus open circuit voltage (“V”) graphs for single junction organic photovoltaic devices using different intermediate layer compositions. FIGS. 4C and 4D show J-V characteristics for four different single junction organic photovoltaic devices. A first curve (“Device A”—solid squares) shows the J-V characteristic for a reference single junction organic photovoltaic device 100 in which the intermediate layer 110 consists solely of a zinc oxide electron transport layer 112. A second curve (“Device E”—solid circles) shows the J-V characteristic for a single junction organic photovoltaic device 100 in which the intermediate layer 110 consists of a zinc oxide electron transport layer 112 and a tungsten oxide hole transport layer 114. A third curve (“Device F”—solid triangles) shows the J-V characteristic for a single junction organic photovoltaic device 100 in which the intermediate layer 110 consists of a zinc oxide electron transport layer 112, a tungsten oxide hole transport layer 114, and an intervening metallic nanostructure layer 116 deposited using the relatively concentrated AgNW1 ink. A fourth curve (“Device G”—inverted triangles) shows the J-V characteristic for a single junction organic photovoltaic device in which the intermediate layer 110 consists of a zinc oxide electron transport layer 112, a tungsten oxide hole transport layer 114, and an intervening metallic nanostructure layer 116 deposited using the relatively dilute AgNW2 ink.

As shown in FIGS. 4C and 4D, organic photovoltaic devices (e.g., Device E) using a tungsten oxide hole transport layer 114 and zinc oxide electron transport layer 112 suffer deficiencies that are similar to those found in the PEDOT/zinc oxide organic photovoltaic devices (e.g., Device B), such as low rectification as a consequence of a high series resistance. The performance of the organic photovoltaic devices using an intermediate layer 110 that includes a zinc oxide electron transport layer 112 and a tungsten oxide hole transport layer 114 improves by interposing a metallic nanostructure layer 116 between the zinc oxide and tungsten oxide layers.

Unlike the PEDOT/zinc oxide intermediate layers 110, in the case of tungsten oxide, a more distinct difference in performance was observed between metallic nanostructure layers formed by depositing the relatively concentrated AgNW1 ink versus the relatively dilute AgNW2 ink. Organic photovoltaic devices (e.g., Device F) using the relatively concentrated AgNW1 ink to form the metallic nanostructure layer 116 were found to suffer from a significantly increased shunt resistance than organic photovoltaic devices (e.g., Device G) that use the relatively dilute AgNW2 ink to form the metallic nanostructure layer 116. Thus, organic photovoltaic devices in which increased shunt resistances are preferable (e.g., organic photovoltaic devices coupled in parallel) may benefit from an intermediate layer 110 containing a metallic nanostructure layer 116 containing a relatively high concentration of metallic nanowires such as that formed using the relatively concentrated AgNW1 ink. On the other hand, organic photovoltaic devices in which reduced shunt resistances are preferable (e.g., organic photovoltaic devices coupled in series) may benefit from an intermediate layer 110 containing a metallic nanostructure layer 116 containing a relatively high concentration metallic nanodots such as that formed using the relatively dilute AgNW2 ink. In either case, the overlying electron transport layer 112 most preferably completely covers the metallic nanostructures in the metallic nanostructure layer 116 to prevent shunts or similar defects within the tandem organic photovoltaic device.

Furthermore, in comparison with the reference devices, the performance of organic photovoltaic devices using an intermediate layer including an electron transport layer 112, a hole transport layer 114, and metallic nanostructure layer 116 were less affected by optical loses occurring in the intermediate layer 110. Organic photovoltaic devices using an intermediate layer 110 including a metallic nanostructure layer 116, such as a silver nanowire layer 116, exhibit a slightly increased current density when compared with a reference single junction organic photovoltaic device 200 using the single zinc oxide buffer layer. These observed differences in current density may be caused by either small variations in the thickness or depth of the active layer 120 in the organic photovoltaic device or by a morphological variations occurring within the zinc oxide layer.

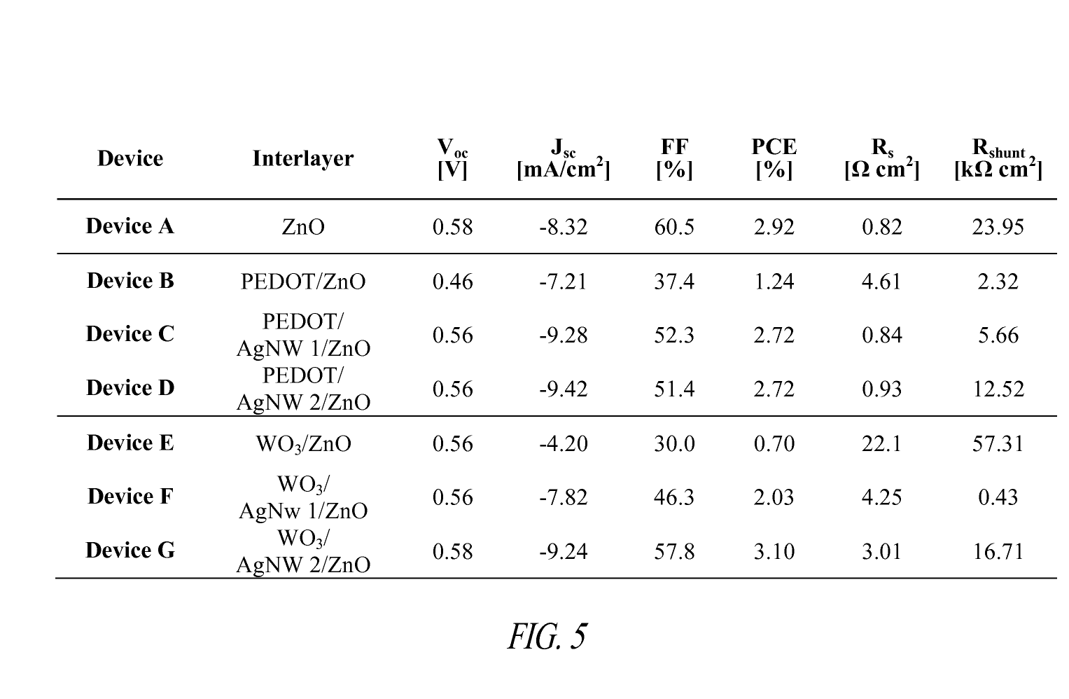

FIG. 5 provides a chart summarizing salient performance parameters of intermediate layers 110 included in FIGS. 4A-4D. The series resistances (Rₛ) of each organic photovoltaic device tabulated in FIG. 5 show a significant reduction when a metallic nanostructure layer 116 was inserted between the hole transport layer 114 and the electron transport layer 112 while the leakage current remained similar to that of the reference organic photovoltaic device. This indicates insertion of the metallic nanostructure (e.g., silver nanostructure) layer 116 enhances the recombination properties of intermediate layer 110. Surprisingly, the silver nanodots (i.e., the physically degraded and/or truncated silver nanowires, or silver nanoparticles that co-precipitated with the silver nanowires and were formulated into the AgNW ink) were found to provide even greater efficiency as recombination centers at the hole transport layer/electron transport layer interface. Compared with silver nanowires, the geometry of the nanodots provide more desirable shunt characteristics, particularly in applications such as tandem organic photovoltaic devices connected in electrical series. Moreover, if more than three nanowires overlap in the metallic nanostructure layer 116 (ref. FIG. 3A) the metallic nanostructure layer 116 may not be fully covered or encapsulated by the overlying electron transport layer 112, causing a high leakage current within the organic photovoltaic device. The presence of such a shunt and resultant high leakage current is consistent with the observed J-V characteristic of Device F (ref. FIG. 4D).

FIG. 6 depicts an illustrative tandem organic photovoltaic device 600 comprising an intermediate layer 110 including an electron transport layer 112, a hole transport layer 114, and an interposed metallic nanostructure layer 116. A first surface 602 of the intermediate layer 110 is disposed proximate a first organic photovoltaic device 610 sensitive to incoming photons in a first band of wavelengths (λₙ₁-λₙₙ) 630. A second surface 604 of the intermediate layer 110 is disposed proximate a second organic photovoltaic device 620 sensitive to incoming photons in a second band of wavelengths (λₘ₁-λₘₘ) 640. In some implementations, the second band of wavelengths 640 may differ (i.e., may include one or more different wavelengths) from the first band of wavelengths 630. In some implementations, the first band of wavelengths and the second band of wavelengths may be similar or identical, for example by encompassing one or more common wavelengths. The layers depicted in FIG. 6 are illustrative and the various electron transport layers, hole transport layers, active layers, and metallic nanostructure layers may be added, deleted, modified or rearranged to modify one or more performance and/or operational parameters of the tandem organic photovoltaic device 600. Additionally, while the interfaces between each of the layers in the tandem organic photovoltaic device 600 are shown as smooth, planar, surfaces for clarity such surfaces may have any surface profile including structured or random patterns and/or roughness.

The intermediate layer 110 includes a first electron transport layer 112 and a first hole transport layer 114 disposed on opposing sides of an interposed metallic nanostructure layer 116. The intermediate layer 110 facilitates the removal of accumulated charge or the recombination of accumulated charge between two adjoining organic photovoltaic devices. In at least some instances, the intermediate layer facilitates the recombination the electrons from the second active layer 622 of the second organic photovoltaic device 620 transported via the first electron transport layer 112 with the holes from the first active layer 612 of the first organic photovoltaic device 610 transported via the first hole transport layer 114.

The first electron transport layer 112 can include any current or future developed material or substance capable of promoting the selective movement or transport of electrons and/or negative electrical charge from the second active layer 622 to the metallic nanostructure layer 116. Non-limiting examples of substances, compounds, or materials useful for providing the first electron transport layer 112 include, oxides of zinc, such as zinc oxide (ZnO); and, oxides of titanium, such as titanium oxide (TiO) and titanium dioxide (TiO₂). The first electron transport layer 112 is most frequently applied as a liquid mixture that includes the electron transport layer substance, compound, or material suspended in a liquid carrier. Such solutions may be spin coated or mechanically leveled across an underlying substrate during application. Other coating and/or leveling methods known in the art may also be employed to dispose the first electron transport layer 112 on an underlying substrate or surface. The thickness of the electron transport layer 112 depends to an extent on the specific substances, compounds, or materials used in forming the electron transport layer 112 and the process/processes used to deposit and/or level the electron transport layer 112 on an underlying substrate or surface. The thickness of the electron transport layer 112 is preferably sufficiently thick to fully encapsulate the metallic nanostructures in the underlying metallic nanostructure layer 116 while sufficiently thin to ensure desirable optical properties are maintained. In at least some implementations, the electron transport layer thicknesses can range from about 30 nanometers (nm) to about 200 nanometers. The thickness or other physical or morphological properties of the electron transport layer 112 may be altered, adjusted, or changed to meet specific organic photovoltaic device performance parameters.

The first hole transport layer 114 can include any current or future developed material or substance capable of promoting the selective movement or transport of holes and/or positive electrical charge from the first active layer 612 or other adjoining structure or layer to the metallic nanostructure layer 116. Example compounds, substances, and/or materials useful for providing the first hole transport layer 112 include, without limitation, poly(3,4-ethylenedioxythiophene)/poly(styrenesulfonate) (“PEDOT:PSS”) and tungsten oxide (WO₃). The first hole transport layer 114 is most frequently applied as a liquid that includes the hole transport layer substance, compound, or material suspended in a liquid carrier. Such solutions may be spin coated or mechanically leveled across an underlying substrate during application. Other coating and/or leveling methods known in the art may also be employed to dispose the first hole transport layer 114 on an underlying substrate or surface. The thickness of the hole transport layer 114 depends to an extent on the specific substances, compounds, or materials used in forming the hole transport layer 114 and the process/processes used to deposit and/or level the hole transport layer 114 on an underlying substrate or surface. In at least some implementations, the hole transport layer thicknesses can range from about 30 nanometers (nm) to about 200 nanometers. The thickness or other physical or morphological properties of the hole transport layer 114 may be altered, adjusted, or changed to meet specific organic photovoltaic device performance parameters.

The metallic nanostructure layer 116 can include any current or future developed metallic nanostructure and/or nanostructures capable of providing at least a portion of a metallic nanostructure layer interposed between the first electron transport layer 112 and the first hole transport layer 114. In at least some implementations, a polymer film may physically link or couple the metallic nanostructure and/or nanostructures to provide a film, sheet, or layer. One or more metals, metal alloys, and/or metal containing compounds may be used to provide all or a portion of the metallic nanostructure layer 116. Example metals include, but are not limited to silver, gold, and platinum, or alloys, compounds or mixtures thereof. In at least some implementations, conductive non-metallic nanostructures (e.g., graphene nanotubes) may be substituted for or replace some or all of the metal nanostructures included in the metallic nanostructure layer 116. The metallic nanostructures can take one or more forms. Example nanostructure forms include, but are not limited to, nanowires, nanotubes, nanodots, and similar solid, semisolid, or hollow nanostructures, or mixtures thereof.

Although not depicted in FIG. 1, in at least some implementations, the intermediate layer 110 may include a low sheet resistance grid interposed between the electron transport layer 112 and the hole transport layer 114. Such a low sheet resistance grid may be incorporated into the intermediate layer 110 either in addition to or in place of the metallic nanostructure layer 116. The low sheet resistance grid provides a low resistance pathway or a network of pathways for current flow, distribution and/or collection within at least the intermediate layer 110. In addition to providing these low resistance pathways, the low sheet resistance grid may also provide a measure of physical strength to the intermediate layer 110. An intermediate layer 110 having such physical strength may be advantageous for example where larger size organic photovoltaic devices 100 are used, for example in large scale organic photovoltaic devices or in conformal organic photovoltaic devices.

The low sheet resistance grid includes any type of electrically conductive structure having appropriate electrical and physical properties, including metallic, non-metallic, or composite structures containing a combination of metallic and non-metallic structures. Examples of low sheet resistance grids include, but are not limited to fine metal mesh (e.g., copper mesh, silver mesh, aluminum mesh, steel mesh, etc.)—deposited e.g. by sputtering or evaporation with post-patterning, preferably e.g. screen-printed metal pastes (e.g. Ag-paste), an embeddable fine metal wire or a printable solution containing one or more residual low resistance components.

The physical size and/or configuration of the low sheet resistance grid is based in whole or in part upon meeting any specified electrical (e.g., sheet resistance) and physical (e.g., surface roughness and/or light transmission) requirements. The size and routing of the conductors forming the low sheet resistance grid form a grid pattern used to deposit or otherwise form at least a portion of the low sheet resistance grid. In some embodiments, the width of the conductive elements forming the low sheet resistance grid can range from about 1 micron to about 300 microns. In some embodiments, the height of the conductive elements forming the low sheet resistance grid can range from about 100 nm to about 100 microns. The open distance between the elements forming the low sheet resistance grid can range from about 100 microns to about 10 mm.

Deposition of the low sheet resistance grid can be accomplished using pre-patterning, post-patterning or any combination thereof. Examples of pre-patterned, printed, low sheet resistance grids include, but are not limited to, printed silver paste grids, printed copper paste grids, micro- or nano-particle paste grids, or similar conductive paste grids. An example post-patterned low sheet resistance grid is provided by the use photo-lithographic development of a previously applied conductive film to produce the low sheet resistance grid. Other example post-patterned low sheet resistance grids include, but are not limited to, low sheet resistance grids deposited via printing, evaporation, sputtering, electro-less or electrolytic plating, solution processing, and the like followed by patterning via photo-lithography, screen printed resist, screen printed etchant, standard etch, laser etch, adhesive lift off stamp, and the like.

The low sheet resistance grid may have any two-dimensional or three-dimensional geometry, shape or configuration needed to achieve a desired sheet resistance while retaining acceptable optical properties. While a greater grid density (i.e., greater low resistance pathway cross sectional area) may reduce the overall sheet resistance achievable within the intermediate layer 110, a high grid density may increase the opacity of the intermediate layer 110 to unacceptable levels. Thus, the pattern selection and physical properties of the low sheet resistance grid is, at times, may represent a compromise based at least in part upon the minimizing the sheet resistance achievable within the intermediate layer 110 while not increasing the opacity of the intermediate layer 110 to an unacceptable degree.

The low sheet resistance grid can have any fixed, geometric or random pattern capable of providing an acceptable sheet resistance. For example, low sheet resistance grid patterns can include regular or irregular width geometric arrangements such as perpendicular lines, angled lines (e.g., forming a “diamond” pattern), and parallel lines. Other patterns can use curved or arc-shaped conductors to achieve complex patterns having uniform or non-uniform sheet resistance, for example where the transparent conductor is intended for a three dimensional application. In some organic photovoltaic modules, the low sheet resistance grid can be formed using two or more patterns, for example a grid formed using parallel lines bounded by a larger pattern, such as a hexagon or rectangle. In another embodiment, the low sheet resistance grid may be a comb-like structure linking series interconnected thin film photovoltaic stripes.

In some instances, the metallic nanostructures can include metallic nanowires having a diameter of from about 15 nanometers (nm) to about 100 nm in diameter and from about 2 microns to about 50 microns in length along a longitudinal axis of the nanowire. The metallic nanowires can include, but are not limited to, silver nanowires, gold nanowires, platinum nanowires, alloys thereof, or combinations thereof. In such implementations, the metallic nanowires can be aligned within all or a portion of the metallic nanostructure layer. For example, the longitudinal axis of the metallic nanowires may be aligned parallel to the first surface of the intermediate layer 110, parallel to the second surface of the intermediate layer or parallel to both the first and second surfaces of the intermediate layer 110.

In other instances, the metallic nanostructures can include metallic nanodots having a continuous or variable cross-section with a diameter of from about 10 nanometers (nm) to about 60 nm. The metallic nanodots can be about 30 nanometers (nm) to about 80 nm in length along a longitudinal axis of the nanodot. The metallic nanodots can assume various physical forms including, but not limited to: conic structures, pyramidic structures, cylindrical structures, or combinations thereof. The metallic nanodots can include, but are not limited to, silver nanodots, gold nanodots, platinum nanodots, nanodot alloys thereof, or combinations thereof. In such implementations, the metallic nanodots can be aligned within all or a portion of the metallic nanostructure layer. For example, the longitudinal axis of the metallic nanodots may be at an angle of from about 1 degree to 90 degrees with respect to the first surface of the intermediate layer, at an angle of from about 1 degree to 90 degrees with respect to the second surface of the intermediate layer or at an angle of from about 1 degree to about 90 degrees with respect to both the first and second surfaces of the intermediate layer.

All or a portion of the metallic nanodots may be present in the metallic nanostructure ink used to provide the metallic nanostructure layer 116. In some instances, all or a portion of the metallic nanodots may be formed by physically, mechanically, or chemically altering and/or decomposing all or a portion of the metallic nanostructures present in the metallic nanostructure ink used in forming the metallic nanostructure layer 116. For example, an ink containing silver nanowires may be physically and/or chemically altered such that at least a portion of the silver nanowires present in the ink are converted to silver nanodots. In yet other instances, the metallic nanostructures can include combinations of two, three, or even more metallic nanostructures. For example, a metallic nanostructure layer 116 may include a combination of metallic nanowires and metallic nanodots.

The metallic nanostructure layer 116 is deposited on or otherwise applied to an underlying substrate or surface as a liquid solution or ink that includes the nanostructures suspended in one or more liquid carriers. Such solutions or inks may be deposited on the underlying substrate or surface and leveled to a defined film thickness via spin coating or mechanically leveling (e.g., via doctor blading or similar mechanical leveling processes) to provide a defined final film thickness (e.g., 60 nm). The thickness of the metallic nanostructure layer 116 depends to an extent on the specific substances, compounds, or materials used in forming the metallic nanostructure layer 116 and the process/processes used to deposit and/or level the metallic nanostructure layer 116 on an underlying substrate or surface. In at least some implementations, the metallic nanostructure layer 116 thicknesses can range from about 30 nanometers (nm) to about 150 nanometers. The thickness or other physical or morphological properties of the metallic nanostructure layer 116 may be altered, adjusted, or changed to meet specific organic photovoltaic device performance parameters.

In one instance, the metallic nanostructure layer 116 may comprise a plurality of metal nanowires, metal nanodots, or combinations thereof embedded in a matrix. As used herein, the term “matrix” refers to a material into which the metal nanowires are dispersed or embedded. Within the matrix, the nanostructures and/or nanowires may be randomly arranged or preferentially aligned along one or more axes. The nanostructures and/or nanowires may be disposed in a uniform or non-uniform manner within the matrix. In at least some instances, the arrangement of the metallic nanostructures within the metallic nanostructure layer 116 may provide one or more preferable physical or electrical properties, for example by providing desirable in-plane or through-plane resistance characteristics. The nanostructures and/or nanowires may or may not extend from one or more surfaces formed by the metallic nanostructure layer 116. The matrix is a host for the nanostructures and/or nanowires and provides physical form to the metallic nanostructure layer 116. The matrix may be selected or configured to protect the nanostructures and/or nanowires from adverse environmental factors, such as chemical, galvanic, or environmental corrosion. In particular, the matrix significantly lowers the permeability of potentially corrosive elements such as moisture, trace amount of acids, oxygen, sulfur and the like, all of which can potentially degrade the nanostructures and/or nanowires embedded in the matrix and/or underlying substrates, surfaces, or structures.

In addition, the matrix contributes to the overall physical and mechanical properties to the metallic nanostructure layer 116. For example, the matrix can promote the adhesion of the metallic nanostructure layer 116 to neighboring electron transport layers 112 and hole transport layers 114 within the intermediate layer 110. The matrix also contributes to the flexibility of the metallic nanostructure layer 116 and to the overall flexibility of organic photovoltaic devices incorporating an intermediate layer 110 that include a metallic nanostructure layer 110, such as the tandem organic photovoltaic device 700.

In at least some instances, the matrix is an optically clear material. A material is considered optically clear if the light transmission of the material is at least 80% in the visible region (a band of wavelengths from about 400 nm to about 700 nm). A multitude of factors determines the optical clarity of the matrix, including without limitation: the refractive index (RI), thickness, consistency of RI throughout the thickness, surface (including interface) reflection, and haze (a scattering loss caused by surface roughness and/or embedded particles). In certain embodiments, the matrix may be thinner, on average, than the metallic nanostructures embedded or otherwise contained in the matrix. For example, the matrix may have a thickness of about 10 nm while the metallic nanostructures (e.g., silver nanowires) have a diameter of about 30 nm and a length of about 50 nm. The matrix can have a refractive index of about 1.3 to about 2.5, or about 1.35 to about 1.8.

In certain embodiments, the matrix is a polymer, which is also referred to as a polymeric matrix. Optically clear polymers are known in the art. Examples of suitable polymeric matrices include, but are not limited to: polyacrylics such as polymethacrylates (e.g., poly(methyl methacrylate)), polyacrylates and polyacrylonitriles, polyvinyl alcohols, polyesters (e.g., polyethylene terephthalate (PET), polyester naphthalate, and polycarbonates), polymers with a high degree of aromaticity such as phenolics or cresol-formaldehyde (Novolacs®), polystyrenes, polyvinyltoluene, polyvinylxylene, polyimides, polyamides, polyamideimides, polyetheramides, polysulfides, polysulfones, polyphenylenes, and polyphenyl ethers, polyurethane (PU), epoxy, polyolefins (e.g. polypropylene, polymethylpentene, and cyclic olefins), acrylonitrile-butadiene-styrene copolymer (ABS), cellulosics, silicones and other silicon-containing polymers (e.g. polysilsesquioxanes and polysilanes), polyvinylchloride (PVC), polyacetates, polynorbornenes, synthetic rubbers (e.g. EPR, SBR, EPDM), and fluoropolymers (e.g., polyvinylidene fluoride, polytetrafluoroethylene (TFE) or polyhexafluoropropylene), copolymers of fluoro-olefin and hydrocarbon olefin (e.g., Lumiflon®), and amorphous fluorocarbon polymers or copolymers (e.g., CYTOP® by Asahi Glass Co., or Teflon® AF by DuPont).

In other embodiments, the matrix is an inorganic material. For example, a sol-gel matrix based on silica, mullite, alumina, SiC, MgO—Al₂O₃—SiO₂, Al₂O₃—SiO₂, MgO—Al₂O₃—SiO₂—Li₂O or a mixture thereof can be used.

In certain embodiments, the matrix itself may have conductive properties. For example, the matrix can be a conductive polymer. Conductive polymers are well known in the art, including without limitation: poly(3,4-ethylenedioxythiophene) (PEDOT), polyanilines, polythiophenes, polypyroles and polydiacetylenes.

In other embodiments, the polymer matrix may be a viscosity modifier, which serves as a binder that immobilizes the nanostructures on a substrate. Examples of suitable viscosity modifiers include hydroxypropyl methylcellulose (HPMC), methyl cellulose, ethyl cellulose, xanthan gum, polyvinyl alcohol, carboxy methyl cellulose, and hydroxy ethyl cellulose.

As used herein the metallic nanostructure layer 116 can refer to the combination of metal nanostructures and/or nanowires and the matrix. Since conductivity is achieved by electrical charge transfer from one metal nanostructure and/or nanowire to another, a sufficient metal nanostructures and/or nanowires density must be present in the metallic nanostructure layer 116 to reach an electrical transfer threshold and provide adequate overall levels of conductivity. As discussed above, the metallic nanostructure layer 116 can include other materials to impart one or more desirable electrical properties or characteristics. In at least some embodiments, all or a portion of the nanowires present in the metallic nanostructure layer 116 can be aligned to provide one or more desirable electrical properties. Such configurations are described in detail in U.S. application Ser. No. 11/871,721, filed Oct. 12, 2007, entitled “Functional Films Formed by Highly Oriented Deposition of Nanowires” and in U.S. application Ser. No. 13/287,881, filed Nov. 2, 2011 entitled “Grid Nanostructure Transparent Conductor For Low Sheet Resistance Applications” both of which, to the extent that they are not inconsistent with information contained herein, are incorporated by reference herein in their entirety. The mechanical and optical properties of the metallic nanostructure layer 116 may be altered, compromised, or otherwise affected by a high solids loading (e.g., nanowires, scattering particles, and other particulate additives) therein. Advantageously, the high aspect ratios of the metal nanowires allow for the formation of a conductive network through the matrix at a threshold surface loading level preferably of about 0.05 μg/cm² to about 10 μg/cm², more preferably from about 0.1 μg/cm² to about 5 μg/cm² and more preferably from about 0.8 μg/cm² to about 3 μg/cm² for silver nanowires. These surface loading levels do not affect the mechanical or optical properties of the metallic nanostructure layer 116. These values depend strongly on the dimensions and spatial dispersion of the nanowires. Advantageously, transparent conductors of tunable electrical conductivity (or surface resistivity) and optical transparency can be provided by adjusting the loading levels of the metal nanowires. In various embodiments, the light transmission of the metallic nanostructure layer 116 is at least 80% and can be as high as 98%. In various embodiments, the light transmission of the metallic nanostructure layer 116 can be at least 50%, at least 60%, at least 70%, or at least 80% and may be as high as at least 91% to 99%.

The first organic photovoltaic device 610 can include any organic photovoltaic device capable of providing a direct current voltage upon exposure to electromagnetic radiation that includes photons falling within a first band of wavelengths 630. The first organic photovoltaic device 610 may be constructed using any current or future developed configuration and/or materials. In some implementations, such as the implementation depicted in FIG. 6, the first organic photovoltaic device 610 can include a transparent electrode 130 and a first active layer 612, with a second electron transport layer 614 interposed between the electrode 130 and the first active layer 612.

The electrode 130 can include any current or future developed optically transparent or translucent electrically conductive material capable of passing photons falling within a first band of wavelengths 630 and photons falling within a second band of wavelengths 640. An example transparent electrode 130 includes indium tin oxide (“ITO”) deposited on a glass substrate, although other materials and substrates may be substituted. The second electron transport layer 614 can include one or more current or future developed materials, compounds, and/or substances capable of facilitating the movement and/or transport of dissociated excitons (i.e., free or unbound electrons) from the first active layer 612 to the electrode 130.

The first active layer 612 can include any current or future developed organic photovoltaic material, compound, or mixture capable of generating excitons (i.e., bound electron/hole pairs) and/or dissociated excitons (i.e., free or unbound electrons and free or unbound holes resulting from dissociated excitons) upon exposure to electromagnetic radiation including photons that fall within the first band of wavelengths 630.

In some instances, the first active layer 612 can include a plurality of electroactive organic compounds (e.g., an electron donor and an electron acceptor) in a bilayer arrangement where each of the compounds are arranged in discrete, planar, and/or homogeneous, layers. In some instances, the first active layer 612 can include a plurality of electroactive organic compounds in a heterojunction arrangement where the compounds are mixed together to form a polymer blend. In some instances, the first active layer 612 can include a plurality of electroactive organic compounds in a graded heterojunction arrangement where the compounds are mixed together in such a way that a gradient between the compounds is formed. In some instances, the first active layer 612 can include a plurality of electroactive organic compounds in a structured bilayer arrangement where the compounds disposed in homogenous layers with an interface that maximizes area of the contact surface between the compounds.

Electroactive electron donor compounds are exemplified by, but are not limited to, phthalocyanine (“H2Pc”); copper phthalocyanine (“CuPc”); zinc phthalocyanine (“ZnPc”); and, phenyl-C61-butyric acid methyl ester (“PCBM”). Electroactive electron acceptor/hole donor compounds are exemplified by, but are not limited to, poly(3-hexylthiophene-2,5-diyl) (“P3HT”); perylenetetracarboxylic bis-benzimidazole (“PTCBI”); C₆₀ fullerenes and C₆₀ fullerene containing molecules such as [6,6]PC₆₁BM, PCBG, and BTPF₆₀; C70 fullerenes and C70 fullerene containing molecules such as [6,6]PC₇₁BM, and BTPF₇₀; and, poly{[2,7-(9,9-bis-(2-ethylhexyl)-fluorene)]-alt-[5,5-(4,7-di-2′-thienyl-2,1,3-benzothiadiazole)]} (“PFDTBT”).

Similarly, the second organic photovoltaic device 620 can include any organic photovoltaic device capable of providing a direct current voltage upon exposure to electromagnetic radiation that includes photons falling within the second band of wavelengths 640. The second organic photovoltaic device 620 may be constructed using any current or future developed configuration and/or materials. In some implementations, such as the implementation depicted in FIG. 6, the second organic photovoltaic device 620 can include an electrode 150 and a second active layer 622, with a second hole transport layer 624 interposed between the electrode 150 and the second active layer 622.

The electrode 150 can include any current or future developed electrically conductive material. An example electrode 150 includes, but is not limited to, an aluminum electrode or a silver electrode, although other materials, compounds, and/or alloys may be combined and/or substituted. The second hole transport layer 624 can include one or more current or future developed materials, compounds, and/or substances capable of facilitating the movement and/or transport of holes from the second active layer 622 to the electrode 150.

The second active layer 622 can include any current or future developed organic photovoltaic material, compound, or mixture capable of generating excitons and/or dissociated excitons upon exposure to electromagnetic radiation that includes photons falling within a second band of wavelengths 640. In some implementations, the second active layer 622 may have a construction and/or composition similar or identical to the first active layer 612. In some implementations, the second active layer 622 may have a construction and/or composition different from the first active layer 612.

In some instances, the second active layer 622 can include a plurality of electroactive organic compounds (e.g., an electron donor and an electron acceptor) in a bilayer arrangement where each of the compounds are arranged in discrete, planar, homogeneous, layers. In some instances, the second active layer 622 can include a plurality of electroactive organic compounds in a heterojunction arrangement where the compounds are mixed together to form a polymer blend. In some instances, the second active layer 622 can include a plurality of electroactive organic compounds in a graded heterojunction arrangement where the compounds are mixed together in such a way that a gradient between the compounds is formed. In some instances, the second active layer 622 can include a plurality of electroactive organic compounds in a structured bilayer arrangement where the compounds disposed in homogenous layers with an interface that maximizes area of the contact surface between the compounds.

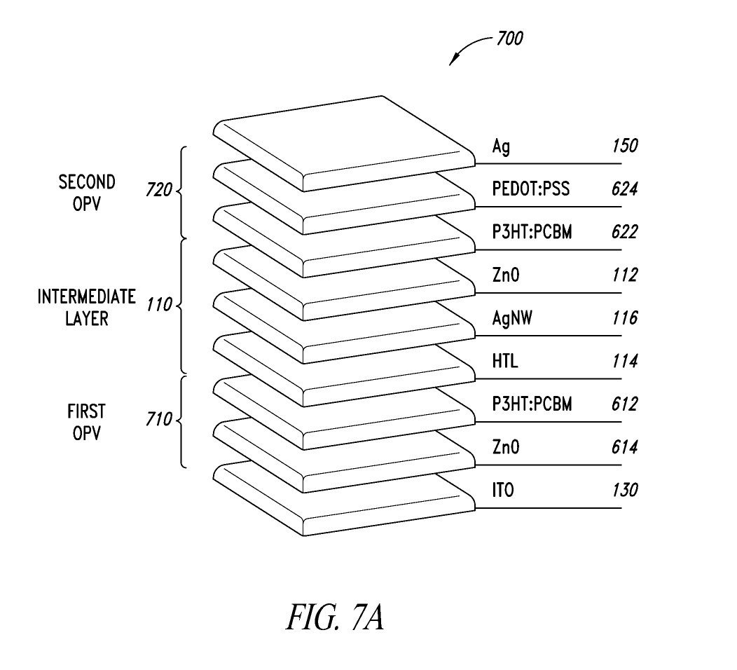

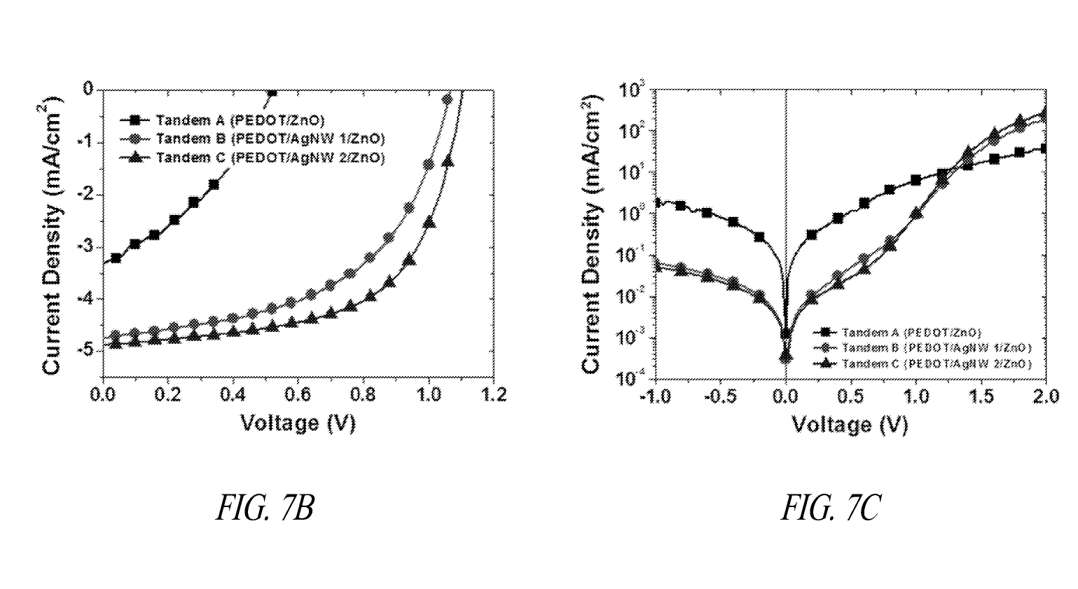

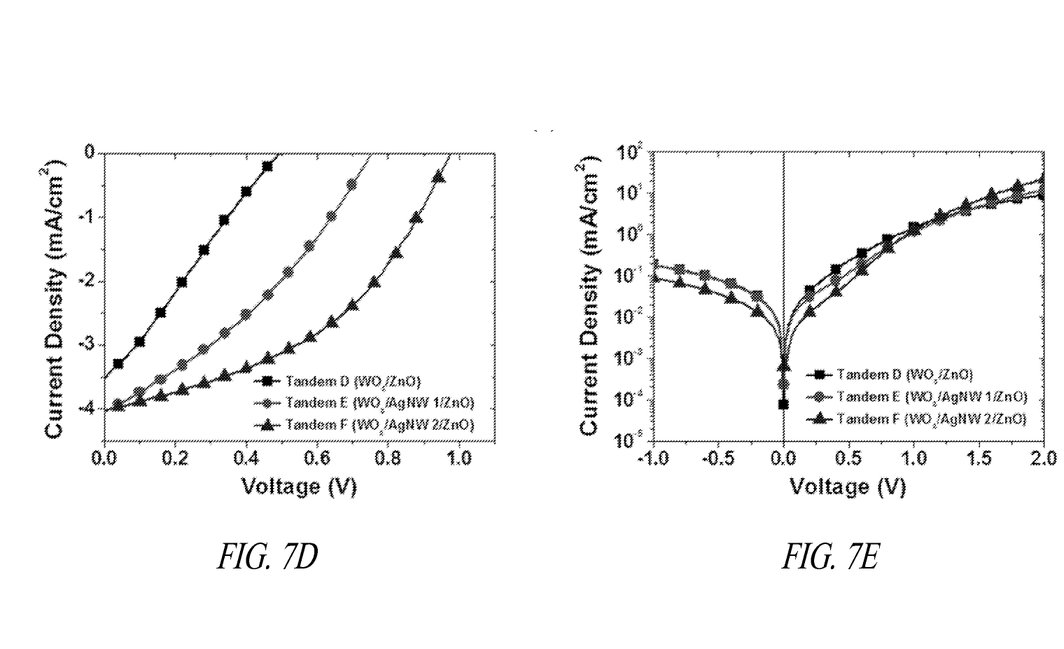

FIG. 7A depicts an exemplary tandem organic photovoltaic device 700 including a first organic photovoltaic device 710, a second organic photovoltaic device 720, and an interposed intermediate layer 110 that includes a metallic nanostructure layer 116, according to an embodiment. In the implementation depicted in FIG. 7A, the first organic photovoltaic device 710 includes a first active layer 612 containing a mixture of P3HT and PCBM and a zinc oxide second electron transport layer 614. The second organic photovoltaic device 720 includes a second active layer 622 containing a mixture of P3HT and PCBM and a PEDOT:PSS second hole transport layer 624. The tandem organic photovoltaic device 700 includes an ITO on glass substrate electrode 130 and a silver electrode 150.

The intermediate layer 110 includes a hole transport layer 114 deposited on the underlying first active layer 612 of the first organic photovoltaic device 610. A metallic nanostructure layer 116 is deposited as a silver nanoparticle ink on the underlying first hole transport layer 114 substrate at relatively low temperatures. The application of the silver nanoparticle ink in a low temperature process protects the underlying first hole transport layer 114 and the underlying P3HT:PCBM first active layer 612. Silver nanoparticle (“AgNW”) ink was prepared from a water based master solution and diluted in isopropyl alcohol at a volume-ratio of 1:5 (“AgNW1”) or 1:10 (“AgNW2”). The silver nanoparticles include at least silver nanowires. A zinc oxide first electron transport layer 112 overlays the metallic nanostructure layer 116. The tandem organic photovoltaic device 700 was examined using a variety of first hole transport layers 114 to determine the optimal configuration of the intermediate layer 110.

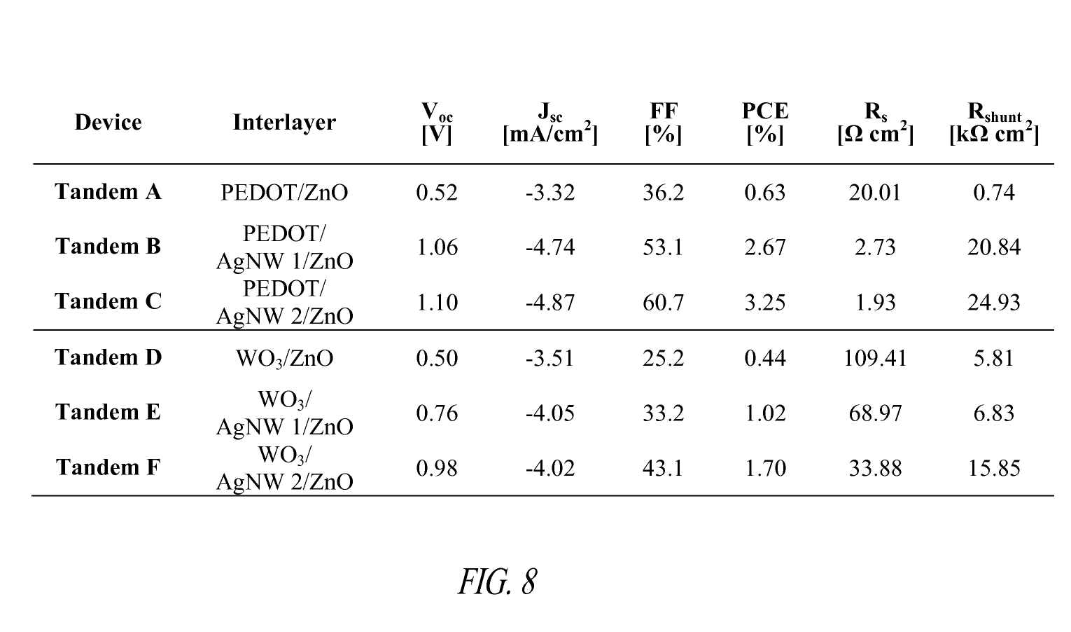

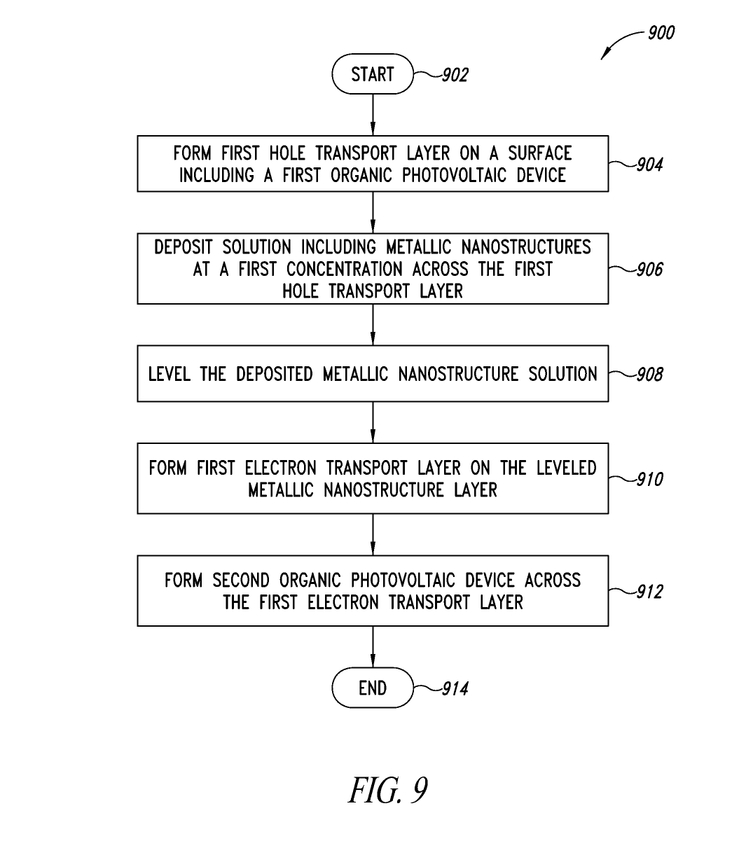

FIGS. 7B-7E show a number of short circuit current density (“J”) versus open circuit voltage (“V”) graphs for the tandem organic photovoltaic device 700 using different intermediate layer compositions. FIG. 8 provides a chart summarizing salient performance parameters of intermediate layers 110 depicted in FIGS. 7B-7E. The performance parameters summarized in FIG. 8 include the open circuit voltage (V_{oc}), short circuit current density (J_{sc}), fill factor (FF—the ratio of the actual maximum obtainable power to the product of the open circuit voltage and short circuit current), the power conversion efficiency (PCE), the series resistance (Rₛ) and the shunt resistance (Rₛₕᵤₙₜ).

FIGS. 7B and 7C show J-V characteristics for a tandem organic photovoltaic device using three different intermediate layer 110 combinations. A first curve (“Tandem A”—solid squares) shows the J-V characteristic for a reference tandem organic photovoltaic device 700 in which the intermediate layer 110 consists of a zinc oxide first electron transport layer 112 and a PEDOT first hole transport layer 114 in the absence of a nanostructure layer 116. A second curve (“Tandem B”—solid circles) shows the J-V characteristic for a tandem organic photovoltaic device 700 in which the intermediate layer 110 consists of a zinc oxide electron transport layer 112, a PEDOT hole transport layer 114, and an interposed metallic nanostructure layer 116 formed by the relatively concentrated AgNW1 ink. A third curve (“Tandem C”—solid triangles) shows the J-V characteristic for a tandem organic photovoltaic device 700 in which the intermediate layer 110 consists of a zinc oxide electron transport layer 112, a PEDOT hole transport layer 114, and an interposed metallic nanostructure layer 116 formed by the relatively dilute AgNW2 ink.

Referring now to FIG. 8, interposing the metallic nanostructure layer 116 between the first electron transport layer 112 and the first hole transport layer 114 improves the open circuit voltage of the tandem organic photovoltaic device 700. As shown in FIG. 8, the tandem organic photovoltaic device 700 using a PEDOT/AgNW2/ZnO intermediate layer 110 (i.e., “Tandem C”) exhibits a fill factor FF of about 61% and an open circuit voltage V_{oc} of 1.10 V. Of note, the open circuit voltage V_{oc} (1.10 V) produced by Tandem C is almost the same as the sum of the open circuit voltage V_{oc} (0.56 V) produced by two single junction organic photovoltaic devices 200 (ref. FIG. 5, “Device D”).

Additionally, the tandem organic photovoltaic device 700 using a PEDOT/AgNW2/ZnO intermediate layer 110 (i.e., “Tandem C”) exhibits a series resistance Rₛ of 1.93 Ωcm², which is only slightly greater than the sum of the series resistance Rₛ (1.86 Ωcm²) produced by two single junction organic photovoltaic devices 200 (ref. FIG. 5, “Device D”). The observed slight increase in series resistance Rₛ of the tandem organic photovoltaic device 700 over the sum of the individual series resistance Rₛ of two single junction organic photovoltaic devices 200 indicates the minimal nature of the losses in the intermediate layer that are attributable to the presence of the metallic nanostructure layer 116, and in particular the relatively dilute AgNW2 used to provide the metallic nanostructure layer 116.

Furthermore, the observed improvement in fill factor FF and open circuit voltage V_{oc} reveal the tandem organic photovoltaic device 700 using a PEDOT/AgNW2/ZnO intermediate layer 110 demonstrates sufficient robustness to protect the underlying first active layer 612 from diffusion during the deposition and leveling of the second active layer 622. The PEDOT/AgNW2/ZnO intermediate layer 110 also demonstrates reasonable efficiency in collecting and recombining the electrons and holes collected from the first organic photovoltaic device 610 and the second organic photovoltaic device 620.

In contrast, the tandem organic photovoltaic device 700 using a PEDOT/ZnO intermediate layer 110 without an interposed metallic nanostructure layer 116 (i.e., “Tandem A”) exhibits a fill factor FF of about 36% and an open circuit voltage V_{oc} of only 0.52 V. Additionally, as evidenced by the relatively high leakage current in FIG. 7C, the combination of PEDOT/ZnO demonstrates insufficient robustness to provide an intermediate layer 110 in the tandem organic photovoltaic device 700. When the shunt resistance Rₛₕᵤₙₜ (25 kΩ cm²) of the tandem organic photovoltaic device 700 using the PEDOT/AgNW2/ZnO intermediate layer 110 (“Tandem C”) is compared to the shunt resistance Rₛₕᵤₙₜ (0.74 kΩ cm²) of the tandem organic photovoltaic device 700 using a PEDOT/ZnO intermediate layer 110 (“Tandem A”) a significant improvement is noted. The observed improvement in shunt resistance demonstrates the enhanced stability of the intermediate layer 110 attributable to interposing a metallic nanostructure layer 116 between the first electron transport layer 112 and the first hole transport layer 114.

FIGS. 7D and 7E show J-V characteristics for a tandem organic photovoltaic device using three different intermediate layer 110 compositions. A first curve (“Tandem D”—solid squares) shows the J-V characteristic for a reference tandem organic photovoltaic device 700 in which the intermediate layer 110 consists of a zinc oxide (“ZnO”) first electron transport layer 112 and a tungsten oxide (WO₃) first hole transport layer 114 in the absence of a metallic nanostructure layer 116. A second curve (“Tandem E”—solid circles) shows the J-V characteristic for a tandem organic photovoltaic device 700 in which the intermediate layer 110 consists of a ZnO electron transport layer 112, a WO₃ hole transport layer 114, and an interposed metallic nanostructure layer 116 formed by the relatively concentrated AgNW1 ink. A third curve (“Tandem F”—solid triangles) shows the J-V characteristic for a tandem organic photovoltaic device 700 in which the intermediate layer 110 consists of a ZnO electron transport layer 112, a WO₃ hole transport layer 114, and an interposed metallic nanostructure layer 116 formed by the relatively dilute AgNW2 ink.

Performance improvements were observed in the tandem organic photovoltaic device 700 employing the WO₃/AgNW2/ZnO intermediate layer 110. As shown in FIG. 8, the tandem organic photovoltaic device 700 using a WO₃/AgNW2/ZnO intermediate layer 110 (i.e., “Tandem F”) exhibits a fill factor FF of about 43% and an open circuit voltage V_{oc} of 0.98 V. Of note, the open circuit voltage V_{oc} (0.98 V) produced by Tandem F is almost the same as the sum of the open circuit voltage V_{oc} (1.16 V) produced by two single junction organic photovoltaic devices 200 (ref. FIG. 5, “Device G”). In contrast, the tandem organic photovoltaic device 700 using a WO₃/ZnO intermediate layer 110 (i.e., “Tandem D”) exhibits an open circuit voltage V_{oc} of only 0.50 V. Additionally, the series resistance Rₛ (34 Ωcm²) of the tandem organic photovoltaic device 700 using a WO₃/AgNW2/ZnO intermediate layer 110 (i.e., “Tandem F”) demonstrates a significant improvement over the series resistance Rₛ (109 Ωcm²) of the tandem organic photovoltaic device 700 using a WO₃/ZnO intermediate layer 110 (i.e., “Tandem D”).

The introduction of a solution processed metallic nanostructure layer 116, and in particular a metallic nanostructure layer 116 that includes nanostructures such as silver nanowires, improves the recombination properties at the interface of the first electron transport layer 112 and first hole transport layer 114. Due to limitations in facilitating the recombination of electrons and holes the efficiency of intermediate layers 110 that include only a ZnO first electron transport layer 112 and either a PEDOT or a WO₃ first hole transport layer 114 in the absence of a metallic nanostructure layer 116 compromise the performance of tandem organic photovoltaic devices 700. The insertion of a solution processed metallic nanostructure layer 116, for example a solution processed silver nanowire layer 116, into the intermediate layer 110 in a tandem organic photovoltaic device 700, shows a functionality similar to the commonly used single buffer layer in single junction organic photovoltaic devices. This indicates the equivalent ohmic contact is formed between first electron transport layer 112 and the first hole transport layer 114 by the interposed metallic nanostructure layer 116.

With the improvement of recombination properties, tandem organic photovoltaic devices 700 incorporating intermediate layers 110 that include a metallic nanostructure layer 116, such as PEDOT/AgNW/ZnO or WO₃/AgNW/ZnO, provide power conversion efficiencies (“PCE”) of 2.72% and 3.10%, respectively. For comparison, the corresponding tandem organic photovoltaic devices 700 not incorporating intermediate layers 110 including a metallic nanostructure layer 116, such as PEDOT/ZnO or WO₃/ZnO intermediate layers 110 provide PCEs of only 1.24% and 0.70%, respectively.

Additionally, intermediate layers 110 incorporating a metallic nanostructure layer 116 were investigated under similar conditions in P3HT:PCBM-based tandem organic photovoltaic devices, suggesting intermediate layers 110 incorporating a metallic nanostructure layer 116 (e.g., first hole transport layer/AgNW/first electron transport layer) are sufficiently robust and improve efficiency to a level suitable for use in tandem organic photovoltaic devices 700.

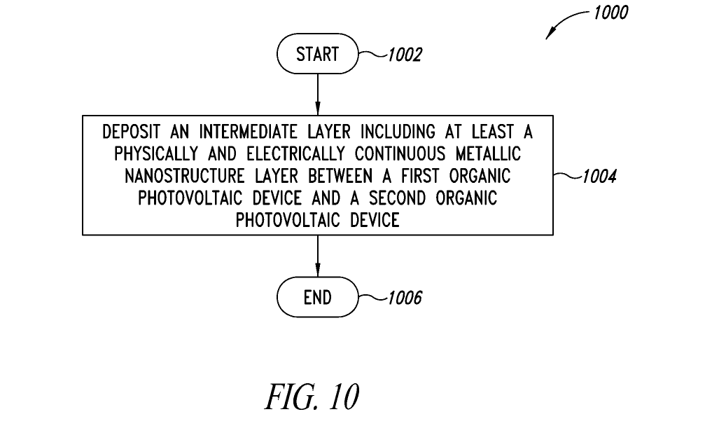

FIG. 9 shows an example method of forming a tandem organic photovoltaic device 700 that includes an intermediate layer 110 having at least one metallic nanostructure layer 116. In tandem organic photovoltaic devices such as that depicted in FIG. 7A, performance of the organic photovoltaic device is dependent at least in part on the ability of the intermediate layer separating the individual organic photovoltaic devices to facilitate the efficient recombination of electrons and holes provided by the individual organic photovoltaic devices.

The intermediate layer 110 includes a metallic nanostructure layer 116 disposed between the first electron transport layer 112 and the first hole transport layer 114. The metallic nanostructure layer 116 promotes the effective recombination of the electrons transported across the first electron transport layer 112 with holes transported across the first hole transport layer 114. In at least some implementations, the metallic nanostructure layer 116 can include a layer of silver nanostructures such as silver nanowires and/or silver nanodots having a thickness of from about 15 nanometers (nm) to about 150 nm. The method of forming a tandem organic photovoltaic device 700 commences at 902.

At 904, a first hole transport layer 114 is formed on a substrate or surface that includes at least a first organic photovoltaic device 610. The first hole transport layer 114 can be formed using any current or future developed deposition and leveling process including, but not limited to, spin coating or mechanical deposition and leveling (e.g., doctor blading). The first hole transport layer 114 can have a thickness of from about 20 nanometers (nm) to about 200 nanometers. In some implementations, the first hole transport layer 114 can include PEDOT and/or one or more PEDOT containing compounds. In some implementations, the first hole transport layer 114 can include tungsten oxide (WO₃) and/or one or more tungsten oxide (WO₃) containing compounds.

At 906, a solution including metallic nanostructures at a first concentration is deposited across all or a portion of the first hole transport layer 114. In at least some implementations, the solution containing the metallic nanostructures includes an aqueous silver nanowire ink containing suspended silver nanowires at a concentration of from about 0.1 weight percent (wt. %) to about 5 wt. %, diluted with isopropyl alcohol at a ratio of from about 1 part by volume silver nanowire ink to about 5 parts by volume isopropyl alcohol to about 1 part by volume silver nanowire ink to about 10 parts by volume isopropyl alcohol. The metallic nanostructure solution may be applied across all or a portion of the first hole transport layer via any current or future developed deposition technique.

At 908 the deposited metallic nanowire solution is leveled across the first hole transport layer 114. Leveling may be accomplished using any current or future developed physical, mechanical, or chemical leveling device, process, or system, for example mechanical leveling via doctor blade. In at least some implementations, metallic nanostructure layer 116 can have a thickness of from about 15 nanometers (nm) to about 150 nm.

At 910, a first electron transport layer 112 is deposited across the surface of the metallic nanostructure layer 116. The first electron transport layer 112 can be formed using any current or future developed deposition and leveling process including, but not limited to, spin coating or mechanical deposition and leveling (e.g., doctor blading). The first electron transport layer 112 can have a thickness of from about 20 nanometers (nm) to about 200 nanometers. In some implementations, the first electron transport layer 112 can include zinc oxide (ZnO) and/or one or more ZnO containing compounds.

At 912 a second organic photovoltaic device 620 is formed across all or a portion of the first electron transport layer 112. The second organic photovoltaic device 620 can include any current or future developed organic photovoltaic device. In at least one implementation, the active layer 622 of the second organic photovoltaic device 620 is formed proximate all or a portion of the first electron transport layer 112. The active layer 622 can include one or more electroactive organic compounds disposed as a number of homogeneous individual layers or as one or more heterogeneous layers that includes a mixture of electroactive organic compounds. The second organic photovoltaic device 620 may also include a second hole transport layer 624 disposed on the side of the active layer 622 opposite the first electron transport layer 112. An electrode 150 may be disposed proximate all or a portion of the second hole transport layer 624. The method of forming a tandem organic photovoltaic device 700 concludes at 912.

FIG. 10 shows an example method of forming a tandem organic photovoltaic device 700 by depositing an intermediate layer 110 having at least one metallic nanostructure layer 116 between a first organic photovoltaic device 610 and a second organic photovoltaic device 620. In tandem organic photovoltaic devices 700 such as that depicted in FIG. 7A, performance of the organic photovoltaic device is dependent at least in part on the ability of the intermediate layer 110 separating the individual first and second organic photovoltaic devices 610, 620 to efficiently recombine electrons and holes provided by the individual first and second organic photovoltaic devices 610, 620.

The intermediate layer 110 includes a metallic nanostructure layer 116 disposed between a first electron transport layer 112 and a first hole transport layer 114. The metallic nanostructure layer 116 facilitates the effective recombination of the electrons transported across the first electron transport layer 112 with the holes transported across the first hole transport layer 114. In at least some implementations, the metallic nanostructure layer 116 can include a layer of silver nanostructures such as silver nanowires and/or silver nanodots in a layer having a thickness of from about 15 nanometers (nm) to about 150 nm. The method of forming a tandem organic photovoltaic device 700 commences at 1002.

At 1004, an intermediate layer 110 including a metallic nanostructure layer 116 having opposed first and second surfaces is deposited between a first organic photovoltaic device 610 and a second organic photovoltaic device 620. In addition to the metallic nanostructure layer 116, the intermediate layer 110 may include any number of first electron transport layers 112 disposed proximate the first surface of the metallic nanostructure layer 116 and any number of hole transport layers 114 disposed proximate the second surface of the metallic nanostructure layer 116. The method of forming a tandem organic photovoltaic device 700 concludes at 1006.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An optical stack, comprising:
an intermediate layer having a first surface and a second surface opposed to the first surface, the intermediate layer comprising:
a first hole transport layer forming at least a portion of the first surface;
a first electron transport layer forming at least a portion of the second surface; and
a metallic nanostructure layer comprising at least one of: a plurality of metallic nanostructures interposed between the first hole transport layer and the first electron transport layer, a low sheet resistance grid interposed between the first hole transport layer and the first electron transport layer, or combinations thereof.

2. The optical stack of claim 1, further comprising a first organic photovoltaic device comprising:
a first active layer having a first surface and a second surface opposed to the first surface, the first active layer sensitive to incoming electromagnetic radiation in a first band of wavelengths,
wherein the first surface of the first active layer is disposed proximate a second electron transport layer, and
wherein the second surface of the first active layer is disposed proximate the first hole transport layer of the intermediate layer.

3. The optical stack of claim 2, further comprising a second organic photovoltaic device comprising:
a second active layer having a first surface and a second surface opposed to the first surface, the second active layer sensitive to incoming electromagnetic radiation in a second band of wavelengths,
wherein the first surface of the second active layer is disposed proximate a second hole transport layer, and
wherein the second surface of the second active layer is disposed proximate the first electron transport layer of the intermediate layer.

4. The optical stack of claim 3, wherein the second band of wavelengths comprises at least one electromagnetic radiation wavelength that is not comprises in the first band of wavelengths.

5. The optical stack of claim 3, wherein the second band of wavelengths does not comprise any electromagnetic radiation wavelengths comprised in the first band of wavelengths.

6. The optical stack of claim 1, wherein the plurality of metallic nanostructures comprise a plurality of metallic nanowires.

7. (canceled)

8. The optical stack of claim 6, wherein a longitudinal axis of each of the plurality of metallic nanowires are parallel to the first surface and the second surface.

9. The optical stack of claim 1, wherein the plurality of metallic nanostructures comprise a plurality of metallic nanodots.

10. (canceled)

11. The optical stack of claim 9, wherein a longitudinal axis of each of the plurality of metallic nanodots are at non-zero angles measured with respect to the first surface and the second surface.

12. The optical stack of claim 1, wherein the plurality of metallic nanostructures comprise a plurality of metallic nanowires and a plurality of metallic nanodots.

13. (canceled)

14. The optical stack of claim 12, wherein a longitudinal axis of each of the plurality of metallic nanowires are parallel to the first surface and the second surface and a longitudinal axis of each of the plurality of metallic nanodots are at non-zero angles measured with respect to the first surface and the second surface.

15. (canceled)

16. (canceled)

17. (canceled)

18. The optical stack of claim 1, wherein the first hole transport layer comprises at least one of: a poly(3,4-ethylenedioxythiophene)/poly(styrenesulfonate) (“PEDOTPSS”) or a tungsten oxide (“WO₃”).

19. The optical stack of claim 1, wherein the first electron transport layer comprises a zinc oxide (“ZnO”).

20. (canceled)

21. (canceled)

22. A method of providing a tandem organic photovoltaic device, comprising:
forming a first hole transport layer across all or a portion of a surface, the surface comprising at least a first organic photovoltaic device;
depositing a metallic nanostructure layer comprising at least one of: a solution comprising a plurality of metallic nanostructures, a low sheet resistance grid, or combinations thereof across all or a portion of the first hole transport layer;
leveling the deposited metallic nanostructure layer across substantially all of the first hole transport layer to provide a leveled metallic nanostructure layer;
forming a first electron transport layer across all or a portion of the leveled metallic nanostructure layer; and
forming a second organic photovoltaic device across all or a portion of the first electron transport layer.

23. The method of claim 22, wherein forming the first hole transport layer across all or a portion of the surface comprises:
depositing a second electron transfer layer across at least a portion of an indium tin oxide (“ITO”) substrate layer that forms at least a portion of the surface;
depositing a first active layer across all or a portion of the second electron transfer layer, the first active layer comprising a poly(3-hexylthiophene) (“P3HT”) polymer and a phenyl-C61-butyric acid methyl ester (“PCBM”) polymer; and
depositing the first hole transport layer across at least a portion of the first active layer.

24. The method of claim 23, wherein depositing the first hole transport layer across at least a portion of the first active layer comprises:
depositing a hole transport material in a substantially uniform thickness across at least a portion of the first active layer, the hole transport material comprising at least one of: a poly(3,4-ethylenedioxythiophene)/poly(styrenesulfate) (“PEDOTPSS”) or a tungsten oxide (“WO₃”).

25. The method of claim 22, wherein depositing the metallic nanostructure layer comprises:
depositing the solution across all or a portion of the first hole transport layer, wherein the solution comprises suspended metallic nanowires in a layer having a substantially uniform thickness.

26. The method of claim 22, wherein depositing the metallic nanostructure layer comprises:
diluting an aqueous metallic nanowire ink that comprises from about 0.1 weight percent (wt. %) to about 5 wt. % suspended silver nanowires with isopropyl alcohol at a ratio of from about 1 part by volume metallic nanowire ink to 5 parts by volume isopropyl alcohol to about 1 part by volume metallic nanowire ink to 10 parts by volume isopropyl alcohol to provide a diluted nanowire ink to form the solution; and
depositing the solution across all or a portion of the first hole transport layer.

27. The method of claim 25, wherein leveling the deposited metallic nanostructure layer across substantially all of the first hole transport layer comprises at least one of mechanically leveling or spin coating the deposited metallic nanowire layer across substantially all of the first hole transport layer to provide a metallic nanostructure film thickness of from about 15 nanometers (nm) to about 150 nm.

28. The method of claim 22, wherein forming a first electron transport layer across all or a portion of the leveled metallic nanostructure layer comprises:
depositing an electron transport material in a substantially uniform thickness across at least a portion of the leveled metallic nanostructure layer, the electron transport material comprising a zinc oxide (“ZnO”).

29. The method of claim 22, wherein forming a second organic photovoltaic device across all or a portion of the first electron transport layer comprises:
depositing a second active layer across at least a portion of the first electron transport layer, the second active layer comprising a poly(3-hexylthiophene) (“P3HT”) polymer and a phenyl-C61-butyric acid methyl ester (“PCBM”) polymer; and
depositing a second hole transport layer across at least a portion of the second active layer.

30. A tandem organic photovoltaic device, comprising:
an intermediate layer comprising:
a first hole transport layer;
a first electron transport layer; and
a metallic nanostructure layer comprising a plurality of metallic nanostructures, the metallic nanostructure layer interposed between the first electron transport layer and the first hole transport layer;
a first organic photovoltaic device comprising:
a first active layer sensitive to incoming electromagnetic radiation in a first band of wavelengths, the first active layer having a first surface and a second surface opposed to the first surface, the first surface of the first active layer disposed proximate the first electron transport layer of the intermediate layer; and
a second hole transport layer disposed proximate all or a portion of the second surface of the first active layer; and
a second organic photovoltaic device conductively coupled to the first organic photovoltaic device and comprising:
a second active layer sensitive to incoming electromagnetic radiation in a second band of wavelengths that comprises at least one electromagnetic radiation wavelength outside of the first band of wavelengths, the second active layer having a first surface and a second surface opposed the first surface, the first surface of the second active layer disposed proximate the first hole transport layer of the intermediate layer; and
a second electron transport layer disposed proximate all or a portion of the second surface of the second active layer.

31. The tandem organic photovoltaic device of claim 30, further comprising:
a first electrode electrically coupled to the second hole transport layer of the first organic photovoltaic device; and
a second electrode electrically coupled to the second electron transport layer of the second organic photovoltaic device.

32. The tandem organic photovoltaic device of claim 31, further comprising:
a third electrode electrically coupled to at least the metallic nanostructure layer.

33. (canceled)

34. (canceled)

35. (canceled)

36. The tandem organic photovoltaic device of claim 30, wherein the first hole transport layer comprises at least one of: a poly(3,4-ethylenedioxythiophene)/poly(styrenesulfonate) (“PEDOT:PSS”) or a tungsten oxide (“WO₃”).

37. The tandem organic photovoltaic device of claim 30, wherein the first electron transport layer comprises a zinc oxide (“ZnO”).

38. (canceled)

39. (canceled)

40. A method of providing a tandem organic photovoltaic device, comprising:
depositing an intermediate layer between a first organic photovoltaic device and a second organic photovoltaic device, the intermediate layer comprises at least a first electron transport layer, a first hole transport layer, and a metallic nanostructure layer interposed between the first electron transport layer and the first hole transport layer.

41. The method of claim 40, wherein depositing the intermediate layer between the first organic photovoltaic device and the second organic photovoltaic device comprises:
depositing the intermediate layer between an active layer of the first organic photovoltaic device and an active layer of the second organic photovoltaic device.

42. The method of claim 41, wherein depositing the intermediate layer between the active layer of the first organic photovoltaic device and the active layer of the second organic photovoltaic device comprises:
depositing at least one of the first electron transport layer or the first hole transport layer on the active layer of the first organic photovoltaic device; and
depositing the active layer of the second organic photovoltaic device on at least one of the first electron transport layer or the first hole transport layer not deposited on the active layer of the first organic photovoltaic device.

43. The method of claim 42, further comprising:
depositing a solution comprising metallic nanostructures between the first electron transport layer and the first hole transport layer; and
leveling the deposited solution to provide the metallic nanostructure layer between the first electron transport layer and the first hole transport layer such that the metallic nanostructure layer has a thickness of from about 15 nanometers (nm) to about 150 nm.

44. The method of claim 43, wherein depositing the solution comprising metallic nanostructures between the first electron transport layer and the first hole transport layer comprises:
forming the solution by diluting an aqueous silver nanowire ink comprising from about 0.1 weight percent (wt. %) silver nanowires in suspension to about 5 wt. % silver nanowires in suspension with isopropyl alcohol at a volume ratio of from about 1 part ink to 5 parts isopropyl alcohol to about 1 part ink to 10 parts isopropyl alcohol; and
depositing the diluted silver nanowire ink between the first electron transport layer and the first hole transport layer.

45. (canceled)

46. (canceled)
